(19) United States
(12) Patent Application Publication
(10) Pub. No.: US 2022/0204814 A1
(43) Pub. Date: Jun. 30, 2022

(54) COMPOSITION FOR FORMING ADHESIVE FILM, ADHESIVE FILM, LAMINATE, METHOD FOR MANUFACTURING LAMINATE, PATTERN PRODUCING METHOD, AND METHOD FOR MANUFACTURING SEMICONDUCTOR ELEMENT

(71) Applicant: FUJIFILM Corporation, Tokyo (JP)

(72) Inventors: Naoya SHIMOJU, Shizuoka (JP); Akihiro HAKAMATA, Shizuoka (JP)

(73) Assignee: FUJIFILM Corporation, Tokyo (JP)

(21) Appl. No.: 17/696,885

(22) Filed: Mar. 17, 2022

Related U.S. Application Data
(63) Continuation of application No. PCT/JP2020/035940, filed on Sep. 24, 2020.

(30) Foreign Application Priority Data
Sep. 26, 2019 (JP) 2019-175857

(51) Int. Cl. C09J 7/30; C09J 7/20; C09J 125/18; C09J 125/02; G03F 7/00; H01L 21/027

(52) U.S. Cl. CPC C09J 7/30; C09J 7/20; C09J 125/18; C09J 2203/326; G03F 7/0002; H01L 21/0271; C09J 125/02

(57) ABSTRACT

Provided are a composition for forming an adhesive film for imprinting, including a resin having a specific aromatic ring and a polymerizable functional group in a side chain, in which the specific aromatic ring is an unsubstituted aromatic ring, or an aromatic ring having one or more substituents, in which a formula weight of each of the one or more substituents is 1000 or less, and a proportion of a polymerizable functional group including a heterocyclic ring in the polymerizable functional group is less than 3 mol %; an adhesive film to which the composition for forming an adhesive film is applied; a laminate; a method for manufacturing a laminate; a pattern producing method; and a method for manufacturing a semiconductor element.

### CROSS-REFERENCE TO RELATED APPLICATIONS

This application is a Continuation of PCT International Application No. PCT/JP2020/035940 filed on Sep. 24, 2020, which claims priority under 35 U.S.C § 119(a) to Japanese Patent Application No. 2019-175857 filed on Sep. 26, 2019. Each of the above application(s) is hereby expressly incorporated by reference, in its entirety, into the present application.

### BACKGROUND OF THE INVENTION

### 1. Field of the Invention

The present invention relates to a composition for forming an adhesive film, an adhesive film, a laminate, a method for manufacturing a laminate, a pattern producing method, and a method for manufacturing a semiconductor element.

### 2. Description of the Related Art

An imprinting method is a technique in which a fine pattern is transferred to a plastic material by pressing a metal mold (generally also called a mold or a stamper) on which a pattern is formed. The imprinting method enables simple and precise production of a fine pattern, and thus is expected to be applied in various fields in recent years. In particular, a nanoimprint technique for forming a fine pattern of a nano-order level is attracting attention.

The imprinting method is roughly classified into a thermal imprinting method and an optical imprinting method according to a transfer method thereof. In the thermal imprinting method, a mold is pressed against a thermoplastic resin heated to a temperature equal to or higher than a glass transition temperature (hereinafter, referred to as a “Tg” in some cases), the thermoplastic resin is cooled, and then the mold is released to form a fine pattern. This method has an advantage that various materials can be selected, but also has problems in that a high pressure is required during pressing, and as the pattern size is finer, the dimensional accuracy is more likely to be reduced due to thermal shrinkage or the like. Meanwhile, in the optical imprinting method, after photocuring is performed in a state where a mold is pressed against a photocurable composition for forming a pattern, the mold is released. In this method, high-pressure application or high-temperature heating is not required, a dimensional change before and after curing is small, and thus there is an advantage that a fine pattern can be formed with high accuracy.

Recently, new developments such as a nanocasting method in which the advantages of both the thermal imprinting method and the optical imprinting method are combined, and a reversal imprinting method for producing a three-dimensional laminated structure have also been reported.

In the optical imprinting method, a composition for forming a pattern is applied onto a substrate, and then a mold made of a light-transmitting material such as quartz is pressed (JP2005-533393A). The composition for forming a pattern is cured by light irradiation in a state where the mold is pressed, and then the mold is released to produce a cured substance to which a desired pattern is transferred.

In such an imprinting method, since it is necessary to release the mold from the composition for forming a pattern while leaving the composition for forming a pattern on the substrate, sufficient adhesiveness between the substrate and the composition for forming a pattern is required. Accordingly, for example, as shown in JP2013-093552A, JP2014-093385A, JP2016-146468A, and JP2017-206695A, a technique for providing, between a substrate and a composition for forming a pattern, an adhesive film for improving the adhesiveness between the substrate and the composition for forming a pattern has been proposed.

### SUMMARY OF THE INVENTION

In recent years, a carbonaceous material has been attracting attention as hard mask material in semiconductor manufacturing. Under such circumstances, in the adhesive film in the related art, in a case where at least a surface of a substrate is the carbonaceous material, adhesiveness of the adhesive film to the substrate is insufficient, and as a result, it is found that adhesiveness between the substrate and the composition for forming a pattern is insufficient.

The present invention has been made in consideration of the aforementioned problems, and an object of the present invention is to provide a composition for forming an adhesive film which can ensure sufficient adhesiveness between a substrate and a composition for forming a pattern in a case where the composition for forming a pattern is applied to a carbonaceous material on a surface of the substrate by an imprinting method.

Another object of the present invention is to provide an adhesive film to which the composition for forming an adhesive film is applied, a laminate, a method for manufacturing the laminate, a pattern producing method, and a method for manufacturing a semiconductor element.

The above-described problems can be solved by using a resin having an aromatic ring and a polymerizable functional group in a side chain. Specifically, the aforementioned problems can be solved by the following unit <1> and preferably by a unit <2> and subsequent units.

<1>

A composition for forming an adhesive film for imprinting, comprising:

a resin having a specific aromatic ring and a polymerizable functional group in a side chain,

in which the specific aromatic ring is an unsubstituted aromatic ring, or an aromatic ring having one or more substituents, in which a formula weight of each of the one or more substituents is 1000 or less, and

a proportion of a polymerizable functional group including a heterocyclic ring in the polymerizable functional group is less than 3 mol %.

<2>

The composition for forming an adhesive film according to <1>,

in which the formula weight of each of the one or more substituents is 250 or less.

<3>

The composition for forming an adhesive film according to <1> or <2>,

in which the specific aromatic ring is a single ring or a fused ring having 2 to 5 rings.

<4>

The composition for forming an adhesive film according to any one of <1> to <3>,

in which the specific aromatic ring is an unsubstituted aromatic ring.

<5>

The composition for forming an adhesive film according to any one of <1> to <4>,

in which the specific aromatic ring is one of a benzene ring, a naphthalene ring, an anthracene ring, or a phenanthrene ring.

<6>

The composition for forming an adhesive film according to any one of <1> to <5>,

in which the specific aromatic ring is linked to a main chain of the resin through a single bond or a linking group having a link length of 1 to 10 atoms.

<7>

The composition for forming an adhesive film according to any one of <1> to <6>,

in which the resin includes at least one of a resin including a repeating unit represented by Formula (AD-1) or a resin including a repeating unit represented by Formula (AD-2) and a repeating unit represented by Formula (AD-3),

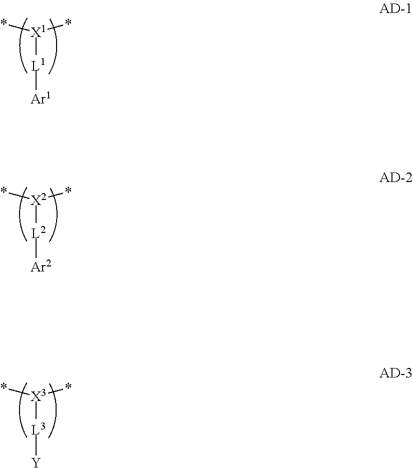

in Formula (AD-1),

X¹ represents a trivalent linking group,

L¹ represents a single bond or a divalent linking group, and

Ar¹ represents a group which includes the specific aromatic ring and the polymerizable functional group, and

* represents a bonding site with a main chain,

in Formula (AD-2) and Formula (AD-3),

X² and X³ each independently represent a trivalent linking group,

L² and L³ each independently represent a single bond or a divalent linking group,

Ar² represents a group which includes the specific aromatic ring and does not include the polymerizable functional group,

Y represents the polymerizable functional group, and

* represents a bonding site with a main chain.

<8>

The composition for forming an adhesive film according to <7>,

in which the linking groups X¹, X², and X³ are each independently a group represented by any one of Formula (AD-X1), Formula (AD-X2), or Formula (AD-X3),

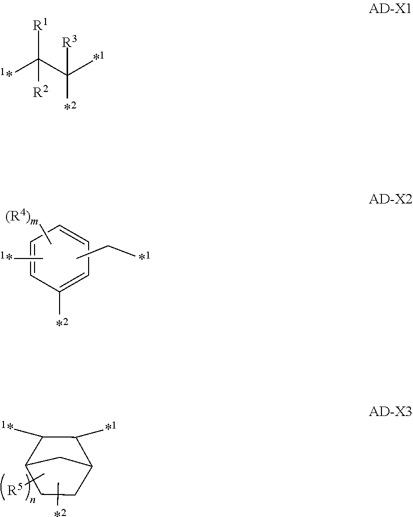

in Formulae (AD-X1) to (AD-X3),

R¹ to R³ each independently represent a hydrogen atom or a monovalent substituent,

R⁴ and R⁵ each independently represent a monovalent substituent,

m and n each independently represent an integer of 0 to 3,

*1 represents a bonding part with a main chain of the resin, and

*2 represents a bonding part with any of the linking groups L¹, L², or L³.

<9>

The composition for forming an adhesive film according to <8>,

in which the linking groups X¹, X², and X³ are groups represented by Formula (AD-X1).

<10>

The composition for forming an adhesive film according to any one of <7> to <9>,

in which the linking groups L¹, L², and L³ include an aromatic ring.

<11>

The composition for forming an adhesive film according to any one of <7> to <10>,

in which a mass ratio C2/C3 of a content C2 of the repeating unit represented by Formula (AD-2) to a content C3 of the repeating unit represented by Formula (AD-3) is 0.33 to 3.0.

<12>

The composition for forming an adhesive film according to any one of <7> to <11>,

in which a proportion of a repeating unit including the specific aromatic ring in the resin is 50% to 100% by mass with respect to all repeating units in the resin.

<13>

The composition for forming an adhesive film according to any one of <7> to <12>,

in which a proportion of a repeating unit including the polymerizable functional group in the resin is 50% to 100% by mass with respect to all repeating units in the resin.

<14>

An adhesive film formed from the composition for forming an adhesive film according to any one of <1> to <13>.

<15>

The adhesive film according to <14>,

in which a film density is 0.90 to 1.60 g/cm³.

<16>

The adhesive film according to <14> or <15>,

in which a surface free energy γₐ of the adhesive film, which is obtained by Expression (1), is 30 to 70 mJ/m²,

$${γ}_{a} = {γ}_{a}^{d} + {γ}_{a}^{p} \qquad Expression ( 1 )$$

in Expression (1),

γₐ^{d} and γₐ^{p} each represent a dispersion component and a polar component of the surface free energy of a surface of the adhesive film, which are derived based on Kaelbel-Uy theory.

<17>

A laminate comprising:

a carbon-containing support in which a carbon content in a depth region of 10 nm from a surface is 50% by mass or more, and

an adhesive film which is formed from the composition for forming an adhesive film according to any one of <1> to <13> and is provided in contact with the carbon-containing support.

<18>

The laminate according to <17>,

in which a surface free energy γ_{ab} at an interface between the carbon-containing support and the adhesive film, which is obtained by Expression (2), is 5.0 mJ/m² or less,

$${γ}_{a b} = {( √ {γ}_{a}^{d} - √ {γ}_{b}^{d} )}^{2} + {( √ {γ}_{a}^{p} - √ {γ}_{b}^{p} )}^{2} \qquad Expression ( 2 )$$

in Expression (2),

γₐ^{d} and γₐ^{p} each represent a dispersion component and a polar component of a surface free energy of a surface of the adhesive film, which are derived based on Kaelbel-Uy theory, and

γ_{b}^{d} and γ_{b}^{p} each represent a dispersion component and a polar component of a surface free energy of a surface of the carbon-containing support, which are derived based on Kaelbel-Uy theory.

<19>

A method for manufacturing a laminate, comprising:

applying the composition for forming an adhesive film according to any one of <1> to <13> onto a carbon-containing support in which a carbon content in a depth region of 10 nm from a surface is 50% by mass or more to form an adhesive film.

<20>

A pattern producing method comprising:

applying a composition for forming a pattern onto the adhesive film obtained by the method for manufacturing a laminate according to <19>;

curing the composition for forming a pattern in a state of being in contact with a mold; and

peeling off the mold from the composition for forming a pattern.

<21>

A method for manufacturing a semiconductor element, comprising:

using the pattern obtained by the pattern producing method according to <20> to manufacture a semiconductor element.

With the composition for forming an adhesive film according to the aspect of the present invention, sufficient adhesiveness between a substrate and a composition for forming a pattern, in a case where the composition for forming a pattern is applied to a carbonaceous material on a surface of the substrate by an imprinting method, can be ensured.

### BRIEF DESCRIPTION OF THE DRAWINGS

FIGS. 1A to 1G are schematic cross-sectional diagrams showing steps of imprinting.

### DESCRIPTION OF THE PREFERRED EMBODIMENTS

Hereinafter, representative embodiments of the present invention will be described. Respective constituent elements will be described based on the representative embodiments for convenience, but the present invention is not limited to such embodiments.

In the present specification, a numerical range expressed using the term “to” means a range which includes the preceding and succeeding numerical values of “to” as a lower limit value and an upper limit value, respectively.

In the present specification, the term “step” is meant to include not only an independent step, but also a step which cannot be clearly distinguished from other steps as long as an intended action of the step is achieved.

In the description of a group (atomic group) in the present specification, in a case where the group is described without specifying whether the group is substituted or unsubstituted, the description means that the group includes both a group having no substituent and a group having a substituent. For example, in a case where a group is simply described as an “alkyl group”, the description means that the alkyl group includes both an alkyl group having no substituent (unsubstituted alkyl group) and an alkyl group having a substituent (substituted alkyl group). In addition, in a case where a group is simply described as an “alkyl group”, the description means that the alkyl group may be chain-like or cyclic, and may be linear or branched in a case where the alkyl group is chain-like.

In the present specification, unless otherwise specified, “exposure” is meant to include not only drawing using light but also drawing using particle rays such as electron beams and ion beams. Examples of energy rays used for the drawing include actinic rays such as a bright line spectrum of a mercury lamp, far ultraviolet rays typified by an excimer laser, extreme ultraviolet rays (EUV light), and X-rays, and particle rays such as electron beams and ion beams.

In the present specification, unless otherwise specified, “light” includes electromagnetic waves having a wavelength in ultraviolet, near-ultraviolet, far-ultraviolet, visible, and infrared regions, and also includes radiation. Examples of the radiation include microwaves, electron beams, extreme ultraviolet rays (EUV), and X-rays. In addition, laser light such as a 248-nm excimer laser, a 193-nm excimer laser, and a 172-nm excimer laser can also be used. The light may be monochromatic light (single-wavelength light) passing through an optical filter, or may be light (composite light) having a plurality of wavelengths.

In the present specification, “(meth)acrylate” means both “acrylate” and “methacrylate” or either of them, “(meth)acryl” means both “acryl” and “methacryl” or either of them, and “(meth)acryloyl” means both “acryloyl” and “methacryloyl” or either of them.

In the present specification, a solid content in a composition means components other than a solvent, and a content (concentration) of the solid content in the composition is represented by the mass percentage of the components other than the solvent with respect to the total mass of the composition, unless otherwise specified.

In the present specification, a temperature is 23° C. and an atmospheric pressure is 101,325 Pa (1 atm), unless otherwise specified.

In the present specification, a weight-average molecular weight (Mw) and a number-average molecular weight (Mn) are each expressed as a value in terms of polystyrene according to gel permeation chromatography (GPC measurement), unless otherwise specified. The weight-average molecular weight (Mw) and the number-average molecular weight (Mn) can be determined, for example, by using HLC-8220 (manufactured by TOSOH CORPORATION), and, as columns, GUARD COLUMN HZ-L, TSKgel Super HZM-M, TSKgel Super HZ4000, TSKgel Super HZ3000, and TSKgel Super HZ2000 (manufactured by TOSOH CORPORATION). In addition, the measurement is performed using tetrahydrofuran (THF) as an eluent, unless otherwise specified. Furthermore, for the detection in the GPC measurement, a detector of ultraviolet rays (UV rays) having a wavelength of 254 nm is used, unless otherwise specified.

In the present specification, regarding a positional relationship of respective layers constituting a laminate, in a case where there is a description of “upper” or “lower”, another layer may be on an upper side or a lower side of a reference layer among a plurality of layers of interest. That is, a third layer or element may be further interposed between the reference layer and the other layer, and the reference layer and the other layer are not necessary to be in contact with each other. In addition, unless otherwise specified, in a case where a direction in which layers are stacked on a substrate is referred to as “upward” or there is a photosensitive layer, a direction from the substrate to the photosensitive layer is referred to as “upward”, and the opposite direction is referred to as “downward”. Furthermore, such setting of upward and downward directions is for convenience in the present specification, and in a practical aspect, the “upward” direction in the present specification may be different from a vertically upward direction.

In the present specification, “imprint” preferably refers to transfer of a pattern with a size of 1 nm to 10 mm, and more preferably refers to transfer (nanoimprint) of a pattern with a size of about 10 nm to 100 μm.

<Composition for Forming an Adhesive Film>

A composition for forming an adhesive film according to an embodiment of the present invention in an imprinting method includes a resin having a specific aromatic ring and a polymerizable functional group (hereinafter, also referred to as a “polymerizable group”) in a side chain. The specific aromatic ring is an unsubstituted aromatic ring, or an aromatic ring having one or more substituents, in which a formula weight of each of the one or more substituents is 1000 or less, and a proportion of a polymerizable functional group including a heterocyclic ring in the polymerizable functional group is less than 3 mol %. In the present specification, the “side chain” means an atomic group branched from a main chain (referring to an atom chain having the maximum number of atoms; in a case where a single ring or fused ring shares two or more atoms with such an atom chain, the single ring or fused ring belongs to the main chain as a whole).

With the composition for forming an adhesive film according to the embodiment of the present invention, sufficient adhesiveness between a substrate and a composition for forming a pattern, in a case where the composition for forming a pattern is applied to a carbonaceous material on a surface of the substrate by an imprinting method, can be ensured. The reason for that is not clear, but it is presumed as follows.

In the composition for forming an adhesive film according to the embodiment of the present invention, since the resin has the specific aromatic ring in the side chain, and the specific aromatic ring is an unsubstituted aromatic ring or an aromatic ring having a substituent having a small formula weight, it is considered that factors which inhibit an interaction (such as n-n interaction) between the specific aromatic ring and a carbon-containing support are reduced, and such interaction occurs efficiently and an adhesive force between the adhesive film and the carbon-containing support is improved. Furthermore, in such an action, since the polymerizable group including a heterocyclic ring may inhibit the above-described interaction between the specific aromatic ring and the carbon-containing support, it has been found that it is preferable that the amount of the polymerizable group including a heterocyclic ring is small. This is because that the polymerizable group including a heterocyclic ring has a large polarity, and in a case where the amount of the polymerizable group including a heterocyclic ring is large, the free energy in the system inside the adhesive film is large. Therefore, in order to reduce this free energy, the polymerizable group including a heterocyclic ring tends to be unevenly distributed on a surface of the adhesive film. In a case where the polymerizable group including a heterocyclic ring is unevenly distributed on the surface of the adhesive film, the above-described interaction between the specific aromatic ring and the carbon-containing support is likely to be inhibited by that amount. Therefore, in the present invention, by setting the proportion of the polymerizable group including a heterocyclic ring in the total polymerizable group to less than 3 mol %, the factors which inhibit the above-described interaction are reduced, and the interaction between the specific aromatic ring and the carbon-containing support effectively occurs. In the present invention, the “carbon-containing support” refers to a support in which a proportion of carbon atoms to total atoms excluding hydrogen atoms is 50% or more in a depth region of 10 nm from a surface. In addition, since the resin has the polymerizable group in the side chain, an adhesive force to the composition for forming a pattern, which is formed on the surface of the other side of the adhesive film (opposite to the side with the carbon-containing support), is ensured. As a result, in a case where the surface of the substrate is a carbonaceous material, it is considered that the adhesiveness between the substrate and the composition for forming a pattern is improved.

Hereinafter, each component of the composition for forming an adhesive film according to the embodiment of the present invention will be described in detail.

<<Resin>>

As described above, the resin has a specific aromatic ring and a polymerizable group in the side chain. A weight-average molecular weight of the resin is preferably 2,000 or more, more preferably 4,000 or more, still more preferably 6,000 or more, and particularly preferably 10,000 or more. The upper limit thereof is preferably 70,000 or less and may be 50,000 or less. A method for measuring the molecular weight is as described above. In a case where the weight-average molecular weight is 2,000 or more, film stability during a heating treatment is improved, which leads to the improvement in a surface condition during the formation of the adhesive film. In addition, in a case where the weight-average molecular weight is 70,000 or less, the solubility in a solvent is improved, and thus the spin coat application and the like are easily performed.

It is sufficient that at least one specific aromatic ring is included in the side chain of a part of repeating units in the resin. The number of specific aromatic rings in one repeating unit is not particularly limited, but is preferably 1 to 5, more preferably 1 to 3, and still more preferably 1 or 2, and may be 1. The number of aromatic rings is counted in units of single rings and fused rings. In a case where a plurality of specific aromatic rings are present in the resin, the plurality of specific aromatic rings may be the same kind or different from each other. In addition, in a case where a plurality of specific aromatic rings are present in the resin, the plurality of specific aromatic rings may be in the same repeating unit or may be in different repeating units. Furthermore, in a case where a plurality of specific aromatic rings are in the same repeating unit, the plurality of specific aromatic rings may be in series on a common side chain or in parallel on a branched side chain.

The specific aromatic ring is preferably a single ring or a fused ring, and more preferably a single ring. In addition, in a case where the specific aromatic ring is a fused ring, the number of rings constituting the fused ring is preferably 2 to 5, more preferably 2 to 4, still more preferably 2 or 3, and particularly preferably 2.

The specific aromatic ring is not particularly limited as long as it interacts closely with the carbon-containing support, and may be an aromatic hydrocarbon ring or an aromatic heterocyclic ring, and is preferably an aromatic hydrocarbon ring. In a case where the specific aromatic ring is an aromatic hydrocarbon ring, the number of carbon atoms in one aromatic ring is preferably 30 or less, more preferably 25 or less, still more preferably 15 or less, and particularly preferably 10 or less. For example, the aromatic hydrocarbon ring is preferably a benzene ring, a naphthalene ring, an anthracene ring, a phenanthrene ring, a tetracene ring, a tetraphene ring, a triphenylene ring, or a pyrene ring, more preferably a benzene ring, a naphthalene ring, an anthracene ring, or a phenanthrene ring, and still more preferably a benzene ring or a naphthalene ring. In a case where the specific aromatic ring is an aromatic heterocyclic ring, the number of atoms (ring members) forming a ring in one aromatic ring is preferably 30 or less, more preferably 25 or less, still more preferably 15 or less, and particularly preferably 10 or less. For example, the aromatic heterocyclic ring is preferably a ring structure including at least one of a nitrogen atom, an oxygen atom, or a sulfur atom in a skeleton, such as a pyrrole ring, a furan ring, a thiophene ring, an imidazole ring, a pyrazole ring, an oxazole ring, a thiazole ring, an indole ring, a benzofuran ring, a benzothiophene ring, a benzimidazole ring, a benzoxazole ring, a benzothiazole ring, a pyridine ring, a pyrimidine ring, a quinoline ring, and a carbazole ring.

As described above, the specific aromatic ring is an unsubstituted aromatic ring, or an aromatic ring having one or more substituents, in which a formula weight of each of the one or more substituents is 1000 or less, and is preferably an unsubstituted aromatic ring. A linking group which links the specific aromatic ring and the main chain of the resin is not treated as the substituent. In a case where the specific aromatic ring has a substituent, the number of substituents is preferably 5 or less, more preferably 3 or less, still more preferably 2 or less, and particularly preferably 1. In addition, the formula weight of each substituent is preferably 500 or less, more preferably 300 or less, still more preferably 250 or less, and particularly preferably 200 or less. As the number of substituents and the formula weight of the substituent are smaller, the interaction between the specific aromatic ring and the carbon-containing support is promoted, and the adhesiveness between the adhesive film and the carbon-containing support is further improved.

The substituent included in the specific aromatic ring is not particularly limited, but for example, is preferably the following substituent T.

Examples of the substituent T include one selected from a halogen atom, a cyano group, a nitro group, a hydrocarbon group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Here, Rt¹ and Rt² each independently represent a hydrogen atom, a hydrocarbon group, or a heterocyclic group. In a case where Rt¹ and Rt² are hydrocarbon groups, Rt¹ and Rt² may be bonded to each other to form a ring.

Regarding the substituent T, examples of the halogen atom include a fluorine atom, a chlorine atom, a bromine atom, and an iodine atom. Examples of the hydrocarbon group include an alkyl group, an alkenyl group, an alkynyl group, and an aryl group. The number of carbon atoms in the alkyl group is preferably 1 to 10, more preferably 1 to 5, and still more preferably 1 or 2. The alkyl group may be linear, branched, or cyclic, and is preferably linear or branched. The number of carbon atoms in the alkenyl group is preferably 2 to 10, more preferably 2 to 5, and particularly preferably 2 or 3. The alkenyl group may be linear, branched, or cyclic, and is preferably linear or branched. The number of carbon atoms in the alkynyl group is preferably 2 to 10 and more preferably 2 to 5. The alkynyl group may be linear or branched. The number of carbon atoms in the aryl group is preferably 6 to 10, more preferably 6 to 8, and still more preferably 6 or 7. The heterocyclic group may be a single ring or a polycyclic ring. The heterocyclic group is preferably a single ring or a polycyclic ring having 2 to 4 rings. The number of heteroatoms constituting the ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 10, more preferably 3 to 8, and still more preferably 3 to 5.

The hydrocarbon group and the heterocyclic group as the substituent T may further have another substituent or may be unsubstituted. Examples of the other substituent here include the above-described substituents T.

Specifically, for example, the above-described substituent T is a halogen atom (particularly, a fluorine atom, a chlorine atom, or a bromine atom), an alkyl group having 1 to 5 carbon atoms (particularly, a methyl group, an ethyl group, or a propyl group), an alkenyl group having 2 to 5 carbon atoms (particularly, an ethenyl group (vinyl group) or a propenyl group), an alkoxy group having 1 to 5 carbon atoms (particularly, a methoxy group, an ethoxy group, or a propoxy group), a hydroxyl group, a thiol group, a carbonyl group, a thiocarbonyl group, a carboxyl group, an amino group, a nitro group, a phenyl group, or the like. In particular, the substituent T is preferably a fluorine atom, a methyl group, an ethyl group, a methoxy group, an ethoxy group, a hydroxyl group, a carbonyl group, or a carboxyl group. These substituents may further have another substituent or may be unsubstituted.

In the composition for forming an adhesive film according to the embodiment of the present invention, it is preferable that the specific aromatic ring is linked to the main chain of the resin through a single bond or a linking group having a link length of 1 to 10 atoms. As a result, an effect of further improving the adhesiveness can be obtained. Here, the link length of the linking group refers to the number of atoms in an atom chain constituting the shortest path among atom chains (at both ends, atoms included in the aromatic ring and the main chain of the resin are not included) linking the specific aromatic ring and the main chain of the resin. For example, as shown in Formula (L-1), in a case where it can be determined that the resin has a phenyl group in the side chain, the number of constituent atoms is counted for the shortest atom chain (moiety of the thick line from positions X1 to Y1 in the formula) between a branch point A1 between the main chain and the side chain of the resin and an aromatic ring B1. In a case of Formula (L-1), the link length of the linking group is 7. In the present specification, an asterisk “*” in a chemical formula indicates a bonding site with another atom which is not specified. In particular, it is preferable that the specific aromatic ring is linked to the main chain of the resin through a single bond.

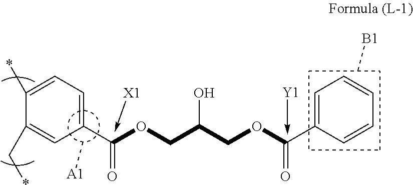

In a case where the specific aromatic ring is linked to the main chain of the resin through a linking group, the upper limit of the link length of the linking group is preferably 8 or less and more preferably 6 or less. The lower limit of the link length of the linking group is not particularly limited, and may be 2 or more or 3 or more.

The linking group which links the specific aromatic ring and the main chain of the resin is preferably a group selected from an alkylene group having 1 to 5 carbon atoms, an alkenylene group having 2 to 5 carbon atoms, an arylene group, —CH═N—, —NH—, —O—, —C(═O)—, —S—, and —C(═S)—, or a group of a combination of two or more these groups, and more preferably a group selected from an alkylene group having 1 to 5 carbon atoms, an arylene group, —O—, and —C(═O)—, or a group of a combination of two or more these groups. The number of carbon atoms in the alkylene group is more preferably 1 to 3 and still more preferably 1 or 2. The number of carbon atoms in the alkenylene group is more preferably 2 or 3 and still more preferably 2. The arylene group may be a single ring or a polycyclic ring, and is preferably a single ring or a bicyclic ring and more preferably a single ring. One ring constituting the arylene group is preferably a 6-membered ring. The above-described linking group may also have a substituent such as the above-described substituent T, but it is preferable that the above-described linking group does not include a polymerizable group as the substituent, and it is more preferable that the above-described linking group is unsubstituted. In a case of having a substituent, for example, the substituent is preferably a fluorine atom, a methyl group, an ethyl group, a methoxy group, an ethoxy group, a hydroxyl group, a carbonyl group, or a carboxyl group. Regarding the above-described linking group, a plurality of the same constituent elements may be selected within the same group.

Specifically, the above-described linking group is preferably a group selected from a methylene group, an ethylene group, a vinylene group, a phenylene group, —CH═N—, —NH—, —O—, —C(═O)—, —S—, or —C(═S)—, or a group of a combination of two or more these groups, more preferably a group selected from a methylene group, an ethylene group, —CH═N—, —NH—, —O—, or —C(═O)—, or a group of a combination of two or more these groups, and still more preferably a group selected from a methylene group, an ethylene group, —O—, and —C(═O)—, or a group of a combination of two or more these groups.

The polymerizable group included in the resin is selected so that the polymerizable group can react with materials in the composition for forming a pattern described later to form a crosslink. It is sufficient that at least one polymerizable group is included in the side chain of a part of repeating units in the resin. The number of polymerizable groups in one repeating unit is not particularly limited, but is preferably 1 to 5, more preferably 1 to 3, still more preferably 1 or 2, and may be 1. In a case where a plurality of polymerizable groups are present in the resin, the plurality of polymerizable groups may be the same kind or different from each other. In addition, in a case where a plurality of polymerizable groups are present in the resin, the plurality of polymerizable groups may be in the same repeating unit or may be in different repeating units. Furthermore, in a case where a plurality of polymerizable groups are in the same repeating unit, the plurality of polymerizable groups may be in series on a common side chain or in parallel on a branched side chain.

The polymerizable group is not particularly limited as long as it can form a crosslink as described above, but is preferably a group having an ethylenically unsaturated bond. In addition, some polymerizable groups may be polymerizable groups including a heterocyclic ring as long as the effects of the present invention are not impaired.

Regarding the polymerizable group, the group having an ethylenically unsaturated bond is preferably a group having a vinyl group or an ethynyl group and more preferably a group having a vinyl group. Examples of the group having a vinyl group include a vinyloxy group (—O—CH═CH₂), a vinylcarbonyl group (acryloyl group) (—CO—CH═CH₂), a vinylamino group (—NR—CH═CH₂), a vinyl sulfide group (—S—CH═CH₂), a vinylsulfonyl group (—SO₂—CH═CH₂), a vinylphenyl (Ph) group (-Ph-CH═CH₂), an acryloyloxy group (—O—CO—CH═CH₂), and an acryloylamino group (—NR—CO—CH═CH₂), a vinyloxy group, an acryloyl group, a vinylphenyl group, an acryloyloxy group, or an acryloylamino group is more preferable, and a vinyloxy group or an acryloyloxy group is still more preferable. In the “—NR—”, R represents a hydrogen atom or a substituent. These groups may have a substituent. Examples of the polymerizable group having a substituent include a methacryloyl group and a methacryloyloxy group. The group having an ethylenically unsaturated bond is particularly preferably a (meth)acryloyloxy group.

The polymerizable group including a heterocyclic ring is, for example, a group including a cyclic ether. The cyclic ether group is, for example, a cyclic alkyleneoxy group having 2 to 6 carbon atoms, and specifically, an epoxy group or an oxetane group. Therefore, the polymerizable group including a cyclic ether group is, for example, an epoxy group or oxetane group itself, a glycidyl group, a glycidyl ether group, or the like.

In the polymerizable group, the proportion of the polymerizable group including a heterocyclic ring is less than 3 mol % as described above. As a result, sufficient adhesiveness between a substrate and a composition for forming a pattern, in a case where the composition for forming a pattern is applied to a carbonaceous material on a surface of the substrate by an imprinting method, can be ensured. The proportion is preferably less than 2 mol %, more preferably less than 1.5 mol %, and still more preferably less than 1 mol %. In particular, it is preferable that the polymerizable group does not contain the polymerizable group including a heterocyclic ring, but the proportion may be 0.1 mol % or more.

Same as the case of the specific aromatic ring, the linking group which links the polymerizable group and the main chain of the resin is preferably a group selected from an alkylene group having 1 to 5 carbon atoms, an alkenylene group having 2 to 5 carbon atoms, an arylene group, —CH═N—, —NH—, —O—, —C(═O)—, —S—, and —C(═S)—, or a group of a combination of two or more these groups. Moreover, specific descriptions of the linking group are the same as in the case of the specific aromatic ring.

The number of atoms (polymerization point distance) in an atom chain constituting the shortest path between a polymerization point in the polymerizable group and the main chain of the resin is preferably 6 or more. In a case where the polymerization point distance is long to some extent, the above-described polymerizable group easily reacts with materials in the composition for forming a pattern described later to form a crosslink, and an adhesive force between the adhesive film and the composition for forming a pattern is further improved. The upper limit of the polymerization point distance is preferably 50 or less, more preferably 35 or less, and still more preferably 20 or less. The lower limit of the polymerization point distance is preferably 7 or more, more preferably 8 or more, and still more preferably 9 or more.

Here, a method for deriving the polymerization point distance will be described. The polymerization point distance is derived by identifying a polymerization point from the polymerizable group, and counting the number of atoms in the shortest atom chain linking this polymerization point and the main chain of the resin. Here, the “polymerization point” means an atomic group, in the polymerizable group, of which a bonding state is changed before and after reaction with other atomic groups. The “change in the bonding state” includes a case where an unsaturated bond is changed to a saturated bond, a case where ring-opening is performed, a case where the number of atoms in a bonding partner is increased or decreased, a case where the atomic species of a bonding partner is changed, a case where some atoms are converted into small molecules (for example, water) and removed, and the like. For example, as shown in Formula (L-2), in a case where it can be determined that the resin has an acryloyloxy group in the side chain, a moiety corresponding to a vinyl group of which the bonding state is changed before and after reaction is recognized as the polymerization point. Moreover, the number of constituent atoms is counted for the shortest atom chain (moiety of the thick line from positions X2 to Y2 in the formula) between a branch point A2 between the main chain and the side chain of the resin and a polymerization point B2. In a case of Formula (L-2), the polymerization point distance is 11.

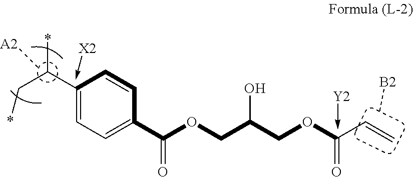

Formula (L-3) shows relationships between representative polymerizable groups and polymerization points. An atomic group surrounded by a dotted line in each of the chemical formulae is a polymerization point.

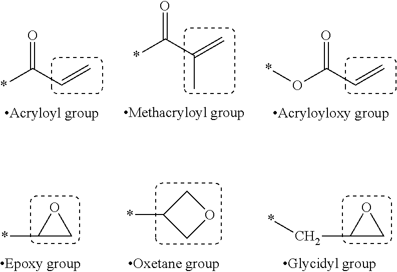

The above-described specific aromatic ring and the above-described polymerizable group, which are included in the resin in the side chain, may be included in the same repeating unit or in different repeating units, and are preferably included in different repeating units. In a case where the specific aromatic ring and the polymerizable group are included in different repeating units, the degree of freedom of each of the specific aromatic ring and the polymerizable group is increased. As a result, the interaction between the specific aromatic ring and the carbon-containing support is promoted, and the polymerizable group promotes the interaction with materials in the composition for forming a pattern. On the other hand, as an aspect in which the specific aromatic ring and the polymerizable group are included in the same repeating unit, for example, an aspect (first aspect) in which the polymerizable group is included in a substituent of the specific aromatic ring, an aspect (second aspect) in which the side chains of the resin are branched and the specific aromatic ring and the polymerizable group are present at different branch destinations, or the like is conceivable. In particular, in the first aspect, from the viewpoints of reducing the formula weight of the substituent of the specific aromatic ring and ensuring a certain length of the polymerization point distance, the polymerization point distance is preferably 3 to 50. The upper limit of the numerical range is more preferably 40 or less and still more preferably 20 or less. In addition, the lower limit of the numerical range is more preferably 4 or more and still more preferably 5 or more.

It is preferable that the resin includes at least one of a resin including a repeating unit represented by Formula (AD-1) or a resin including a repeating unit represented by Formula (AD-2) and a repeating unit represented by Formula (AD-3). The former corresponds to the aspect in which the specific aromatic ring and the polymerizable group are included in the same repeating unit, and the latter corresponds to the aspect in which the specific aromatic ring and the polymerizable group are included in different repeating units.

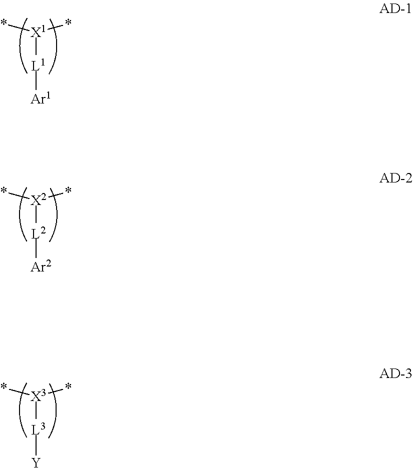

In Formula (AD-1),

X¹ represents a trivalent linking group,

L¹ represents a single bond or a divalent linking group, and

Ar¹ represents a group which includes the specific aromatic ring and the polymerizable functional group and

* represents a bonding site with a main chain;

in Formula (AD-2) and Formula (AD-3),

X² and X³ each independently represent a trivalent linking group,

L² and L³ each independently represent a single bond or a divalent linking group,

Ar² represents a group which includes the specific aromatic ring and does not include the polymerizable functional group,

Y represents the polymerizable functional group, and

* represents a bonding site with a main chain.

The formula weights of respective repeating units are each independently preferably 50 to 1500. The upper limit of the numerical range is more preferably 800 or less and still more preferably 600 or less. In addition, the lower limit of the numerical range is more preferably 80 or more and still more preferably 100 or more.

X¹, X², and X³ are each independently preferably a hydrocarbon group which is linear, branched, or cyclic and is substituted or unsubstituted. Here, the number of carbon atoms in the hydrocarbon group is preferably 2 to 20, more preferably 2 to 15, and still more preferably 2 to 10. In particular, X¹, X², and X³ are each independently preferably a group represented by any one of Formula (AD-X1), Formula (AD-X2), or Formula (AD-X3), and more preferably a group represented by Formula (AD-X1).

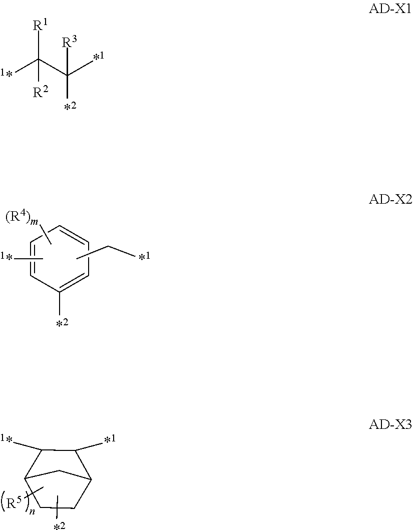

In Formulae (AD-X1) to (AD-X3),

R to R³ each independently represent a hydrogen atom or a monovalent substituent,

R⁴ and R⁵ each independently represent a monovalent substituent,

m and n each independently represent an integer of 0 to 3,

*1 represents a bonding part with a main chain of the resin, and

*2 represents a bonding part with any of the linking groups L¹, L², or L³.

In Formulae (AD-X1) to (AD-X3), the monovalent substituent as R¹ to R⁵ is preferably an alkyl group, a halogen atom, a hydroxyl group, or an alkoxy group. Here, an alkyl moiety in the alkyl group and the alkoxy group is more preferably a linear or branched alkyl group having 1 to 10 carbon atoms, still more preferably a linear or branched alkyl group having 1 to 5 carbon atoms, particularly preferably an alkyl group having 1 to 3 carbon atoms, and most preferably a methyl group. The halogen atom is preferably a fluorine atom, a chlorine atom, or a bromine atom, more preferably a fluorine atom or a chlorine atom, and still more preferably a fluorine atom. m and n are each independently preferably 0 to 2 and more preferably 0 or 1, and may be 0. A plurality of R⁴'s in parentheses may be the same or different from each other. In addition, a plurality of R⁵'s in parentheses may also be the same or different from each other.

Specifically, in Formula (AD-X1), R¹ to R³ are each independently preferably a hydrogen atom, a halogen atom, a methyl group, an ethyl group, a propyl group, a hydroxyl group, a methoxy group, an ethoxy group, or a propoxy group, more preferably a hydrogen atom, a fluorine atom, a methyl group, a hydroxyl group, or a methoxy group, and still more preferably a hydrogen atom, a fluorine atom, or a methyl group. In addition, in Formulae (AD-X2) and (AD-X3), R⁴ and R⁵ are each independently preferably a halogen atom, a methyl group, an ethyl group, a propyl group, a hydroxyl group, a methoxy group, an ethoxy group, or a propoxy group, more preferably a fluorine atom, a methyl group, a hydroxyl group, or a methoxy group, and still more preferably a fluorine atom or a methyl group.

In Formulae (AD-1) to (AD-3), the divalent linking groups as L¹, L², and L³ are each independently preferably a group selected from an alkylene group having 1 to 5 carbon atoms, an alkenylene group having 2 to 5 carbon atoms, an arylene group, —CH═N—, —NH—, —O—, —C(═O)—, —S—, and —C(═S)—, or a group of a combination of two or more these groups, and more preferably a group selected from an alkylene group having 1 to 5 carbon atoms, an arylene group, —O—, and —C(═O)—, or a group of a combination of two or more these groups. The number of carbon atoms in the alkylene group is more preferably 1 to 3 and still more preferably 1 or 2. The number of carbon atoms in the alkenylene group is more preferably 2 or 3 and still more preferably 2. The arylene group may be a single ring or a polycyclic ring, and is preferably a single ring or a bicyclic ring and more preferably a single ring. One ring constituting the arylene group is preferably a 6-membered ring. The above-described linking group may also have a substituent such as the above-described substituent T, but it is preferable that the above-described linking group does not include a polymerizable group as the substituent, and it is more preferable that the above-described linking group is unsubstituted. In a case of having a substituent, for example, the substituent is preferably a fluorine atom, a methyl group, an ethyl group, a methoxy group, an ethoxy group, a hydroxyl group, a carbonyl group, or a carboxyl group. Regarding the above-described divalent linking group, a plurality of the same constituent elements may be selected within the same group.

Specifically, the above-described divalent linking group as L¹, L², and L³ is preferably a group selected from a methylene group, an ethylene group, a vinylene group, a phenylene group, —CH═N—, —NH—, —O—, —C(═O)—, —S—, or —C(═S)—, or a group of a combination of two or more these groups, more preferably a group selected from a methylene group, an ethylene group, —CH═N—, —NH—, —O—, or —C(═O)—, or a group of a combination of two or more these groups, and still more preferably a group selected from a methylene group, an ethylene group, —O—, and —C(═O)—, or a group of a combination of two or more these groups.

It is also preferable that L¹, L², and L³ have an arylene group such as a phenylene group, that is, have an aromatic ring. In such cases, regardless of whether the aromatic ring meets requirements for the specific aromatic ring, an interaction between the aromatic ring and the carbon-containing support may occur. This is because the adhesiveness between the adhesive film and the carbon-containing support may be further improved. In particular, it is preferable that the aromatic ring included in L¹, L², and L³ also meets the requirements for the specific aromatic ring (that is, a formula weight of each substituent is 1000 or less). As a result, the above-described adhesiveness is further improved.

In Formulae (AD-1) and (AD-2), as described above, the specific aromatic ring in Ar¹ and Ar² is not particularly limited as long as it interacts closely with the carbon-containing support, and may be an aromatic hydrocarbon ring or an aromatic heterocyclic ring, and is preferably an aromatic hydrocarbon ring. In addition, the preferred aspect of the aromatic ring is also as described above. For example, the aromatic ring is preferably a benzene ring, a naphthalene ring, an anthracene ring, a phenanthrene ring, a tetracene ring, a tetraphene ring, a triphenylene ring, or a pyrene ring, more preferably a benzene ring, a naphthalene ring, an anthracene ring, or a phenanthrene ring, and still more preferably a benzene ring or a naphthalene ring.

In Formulae (AD-1) to (AD-3), as described above, the polymerizable group in Ar¹ and Y are not particularly limited as long as they can react with materials in the composition for forming a pattern described later to form a crosslink, but a group having an ethylenically unsaturated bond is preferable and a group including a cyclic ether group is more preferable. In addition, the preferred aspect of the polymerizable group is also as described above. Examples of the polymerizable group include a vinyloxy group (—O—CH═CH₂), a vinylcarbonyl group (acryloyl group) (—CO—CH═CH₂), a vinylamino group (—NR—CH═CH₂), a vinyl sulfide group (—S—CH═CH₂), a vinylsulfonyl group (—SO₂—CH═CH₂), a vinylphenyl (Ph) group (-Ph-CH═CH₂), an acryloyloxy group (—O—CO—CH═CH₂), and an acryloylamino group (—NR—CO—CH═CH₂), a vinyloxy group, an acryloyl group, a vinylphenyl group, an acryloyloxy group, or an acryloylamino group is more preferable, and a vinyloxy group or an acryloyloxy group is still more preferable. In the “—NR—”, R represents a hydrogen atom or a substituent. These groups may have a substituent. In a case of having a substituent, for example, the substituent is preferably a fluorine atom, a methyl group, an ethyl group, a methoxy group, an ethoxy group, a hydroxyl group, a carbonyl group, or a carboxyl group. Examples of the polymerizable group having a substituent include a methacryloyl group and a methacryloyloxy group. The group having an ethylenically unsaturated bond is particularly preferably a (meth)acryloyloxy group.

Furthermore, the resin also preferably includes at least one of the following six types of resins.
resin including a repeating unit represented by Formula (AD-4)
resin including a repeating unit represented by Formula (AD-5) and a repeating unit represented by Formula (AD-6)
resin including a repeating unit represented by Formula (AD-7)
resin including a repeating unit represented by Formula (AD-8) and a repeating unit represented by Formula (AD-9)
resin including a repeating unit represented by Formula (AD-10)
resin including a repeating unit represented by Formula (AD-li) and a repeating unit represented by Formula (AD-12)

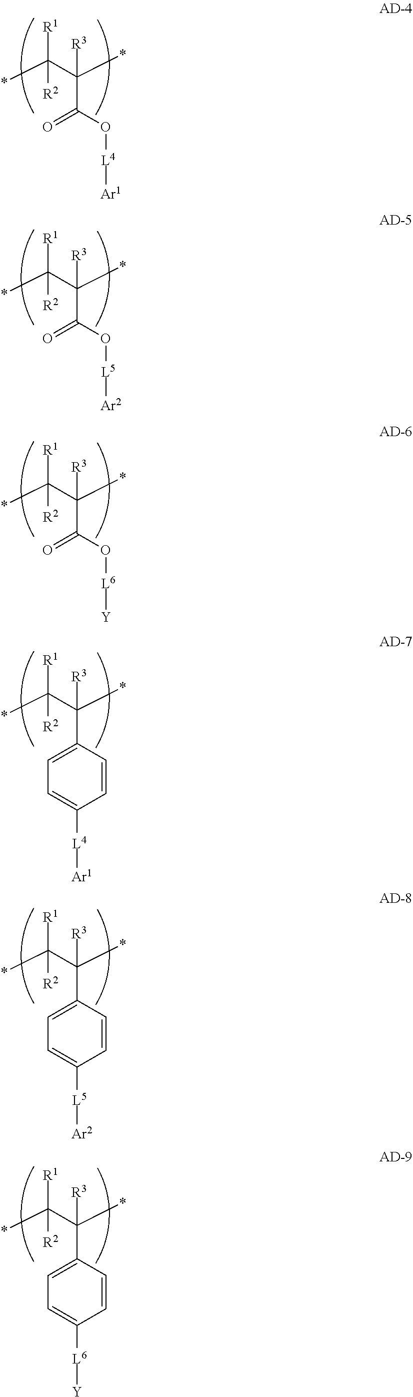

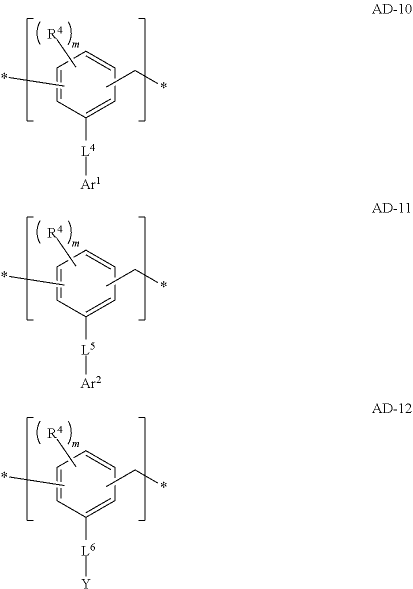

In Formulae (AD-4) to (AD-12),

R¹ to R³ are the same as R¹ to R³ in Formula (AD-X1),

R⁴ and m are the same as R⁴ and m in Formula (AD-X2),

L⁴ to L⁶ represent a single bond or a divalent linking group,

Ar¹ is the same as Ar¹ in Formula (AD-1),

Ar² is the same as Ar² in Formula (AD-2), and

Y is the same as Y in Formula (AD-3).

Each element is independent unless otherwise specified.

Same as L¹ to L³, the divalent linking groups as L⁴ to L⁶ are each independently preferably a group selected from an alkylene group having 1 to 5 carbon atoms, an alkenylene group having 2 to 5 carbon atoms, an arylene group, —CH═N—, —NH—, —O—, —C(═O)—, —S—, and —C(═S)—, or a group of a combination of two or more these groups, and more preferably a group selected from an alkylene group having 1 to 5 carbon atoms, an arylene group, —O—, and —C(═O)—, or a group of a combination of two or more these groups. The number of carbon atoms in the alkylene group is more preferably 1 to 3 and still more preferably 1 or 2. The number of carbon atoms in the alkenylene group is more preferably 2 or 3 and still more preferably 2. The arylene group may be a single ring or a polycyclic ring, and is preferably a single ring or a bicyclic ring and more preferably a single ring. One ring constituting the arylene group is preferably a 6-membered ring. The above-described linking group may also have a substituent such as the above-described substituent T, but it is preferable that the above-described linking group does not include a polymerizable group as the substituent, and it is more preferable that the above-described linking group is unsubstituted. In a case of having a substituent, for example, the substituent is preferably a fluorine atom, a methyl group, an ethyl group, a methoxy group, an ethoxy group, a hydroxyl group, a carbonyl group, or a carboxyl group. Regarding the above-described divalent linking group, a plurality of the same constituent elements may be selected within the same group.

Specifically, the above-described divalent linking group as L⁴ to L⁶ is preferably a group selected from a methylene group, an ethylene group, a vinylene group, a phenylene group, —CH═N—, —NH—, —O—, —C(═O)—, —S—, or —C(═S)—, or a group of a combination of two or more these groups, more preferably a group selected from a methylene group, an ethylene group, —CH═N—, —NH—, —O—, or —C(═O)—, or a group of a combination of two or more these groups, and still more preferably a group selected from a methylene group, an ethylene group, —O—, and —C(═O)—, or a group of a combination of two or more these groups.

In particular, it is also preferable that the repeating unit represented by each of Formulae (AD-4), (AD-6), (AD-7), (AD-9), (AD-10), and (AD-12) are a repeating unit represented by each of Formulae (AD-4b), (AD-6b), (AD-7b), (AD-9b), (AD-10b), and (AD-12b), respectively. These examples are examples in which each repeating unit includes a group having an ethylenically unsaturated bond as the polymerizable group. In the following formulae, Ar⁵'s each independently represent a divalent group including the specific aromatic ring, R⁶'s each independently represent a hydrogen atom or an unsubstituted or substituted methyl group, and other symbols are as described above. Ar⁵ particularly preferably has a benzene ring.

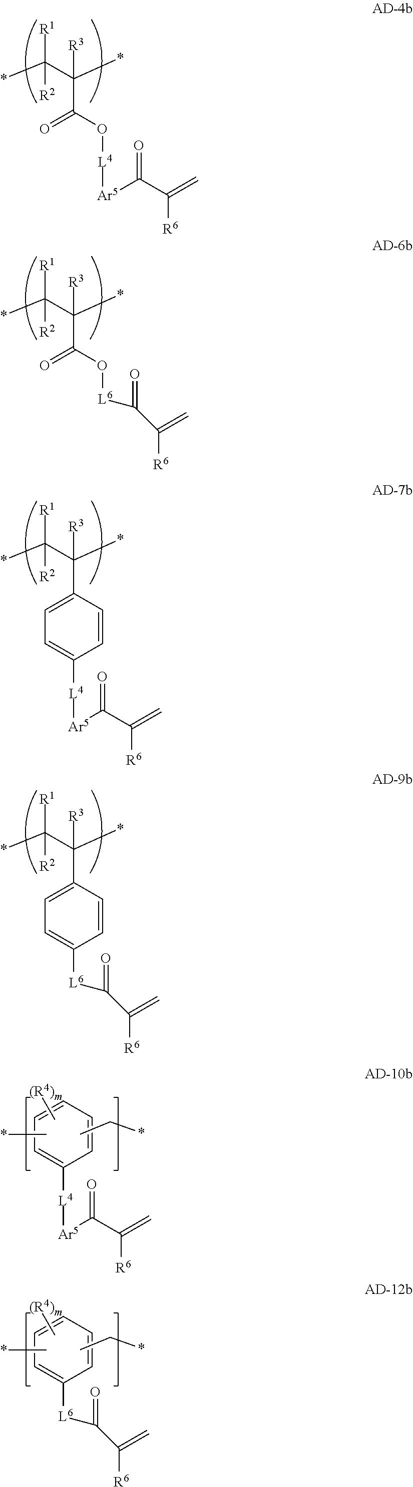

In the resin according to the composition for forming an adhesive film according to the embodiment of the present invention, a mass ratio C2/C3 of a content C2 of the above-described repeating unit represented by Formula (AD-2) to a content C3 of the above-described repeating unit represented by Formula (AD-3) is preferably 0.33 to 3.0. In a case where the mass ratio C2/C3 is within the above-described numerical range, the effect of further improving the adhesiveness is obtained. Further, the upper limit of the above-described numerical range is preferably 2.8 or less, more preferably 2.5 or less, and still more preferably 2 or less. In addition, the lower limit of the above-described numerical range is preferably 0.3 or more, still more preferably 0.5 or more, and still more preferably 0.8 or more.

In the resin according to the composition for forming an adhesive film according to the embodiment of the present invention, a proportion of the repeating unit including the specific aromatic ring is preferably 50% to 100% by mass with respect to all repeating units in the resin. As a result, the number of points where the interaction between the specific aromatic ring and the carbon-containing support occurs increases, and the adhesiveness between the adhesive film and the carbon-containing support is further improved. The upper limit of the above-described numerical range may be 95% by mass or less or 90% by mass or less. In addition, the lower limit of the above-described numerical range is preferably 55% by mass or more, more preferably 58% by mass or more, and still more preferably 60% by mass or more.

In addition, in the resin according to the composition for forming an adhesive film according to the embodiment of the present invention, a proportion of the repeating unit including the polymerizable functional group is preferably 50% to 100% by mass with respect to all repeating units in the resin. As a result, the number of points where a crosslinking reaction occurs between the polymerizable group and materials in the composition for forming a pattern increases, and the adhesiveness between the adhesive film and the composition for forming a pattern is further improved. The upper limit of the above-described numerical range may be 95% by mass or less or 90% by mass or less. In addition, the lower limit of the above-described numerical range is preferably 55% by mass or more, more preferably 58% by mass or more, and still more preferably 60% by mass or more.

Preferred specific examples of the repeating unit represented by Formula (AD-1) include the following structures. However, the present invention is not limited thereto. In the following exemplified chemical formulae, R⁶'s each independently represent a hydrogen atom or an unsubstituted or substituted methyl group, and Z's each independently represent a bond including a heteroatom (—NR⁶, —O—, or —S—).

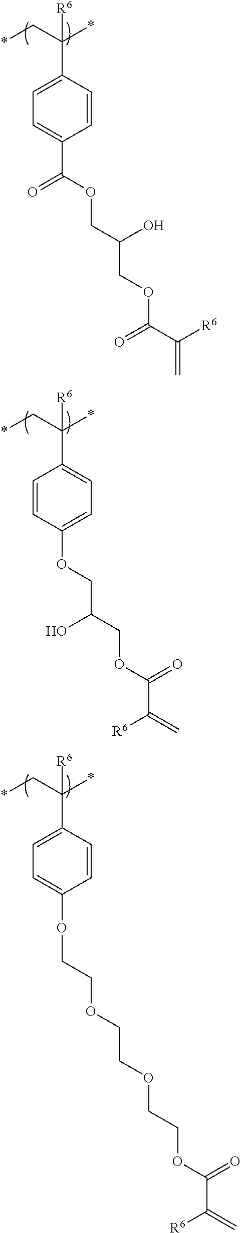

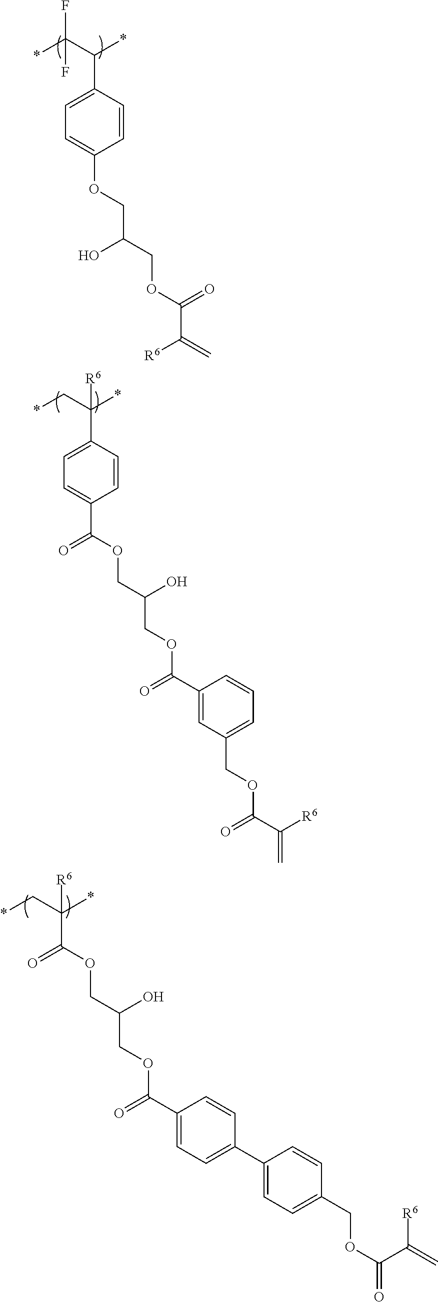

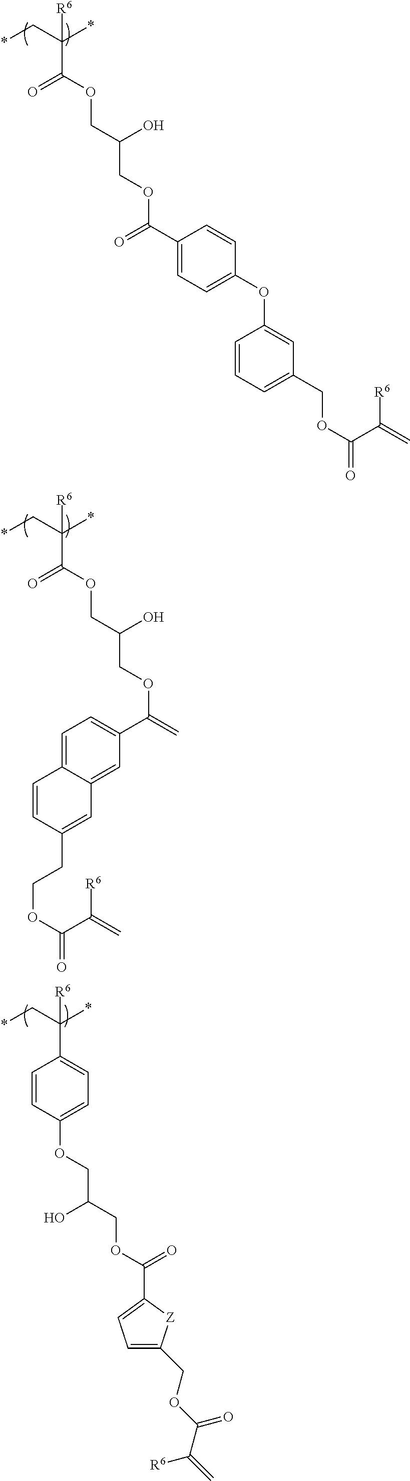

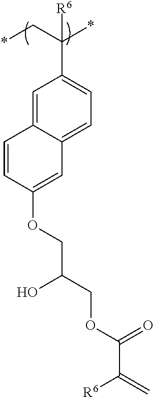

Preferred specific examples of the repeating unit represented by Formula (AD-2) include the following structures. However, the present invention is not limited thereto. In the following exemplified chemical formulae, R⁶'s each independently represent a hydrogen atom or an unsubstituted or substituted methyl group, and Z's each independently represent a bond including a heteroatom (═N—, —NR⁶, —O—, or —S—).

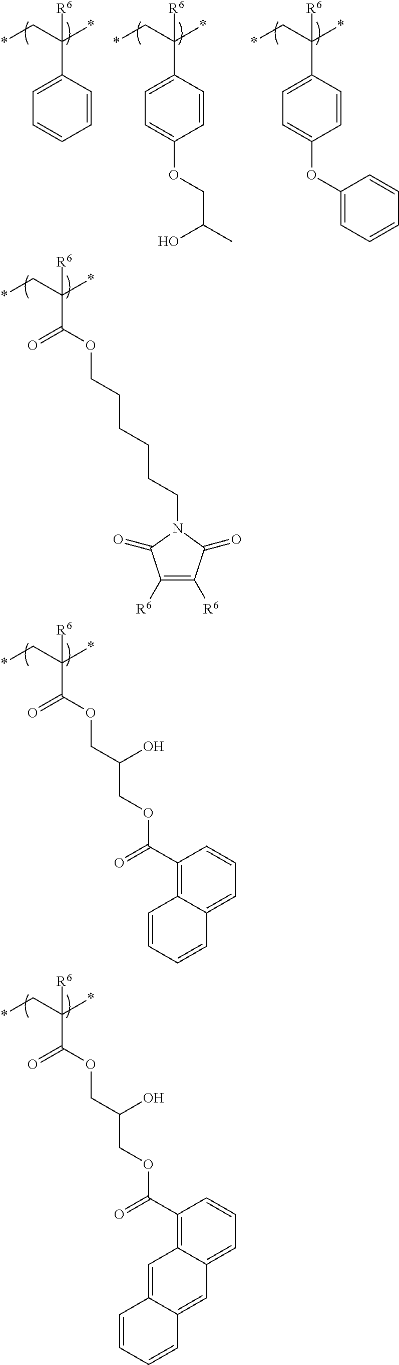

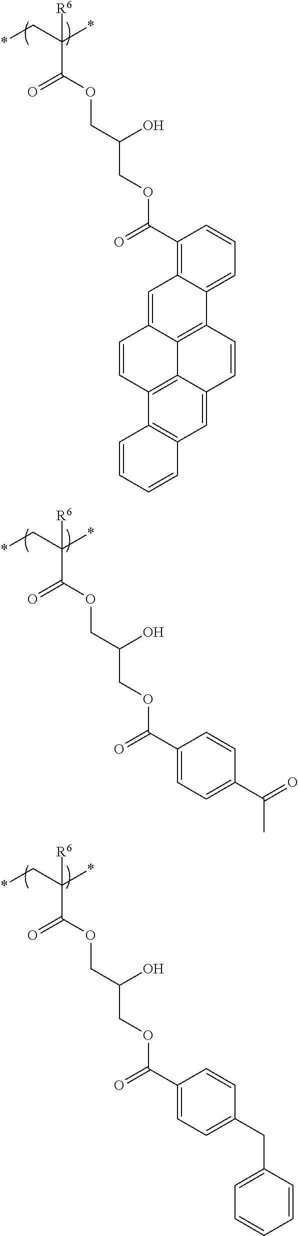

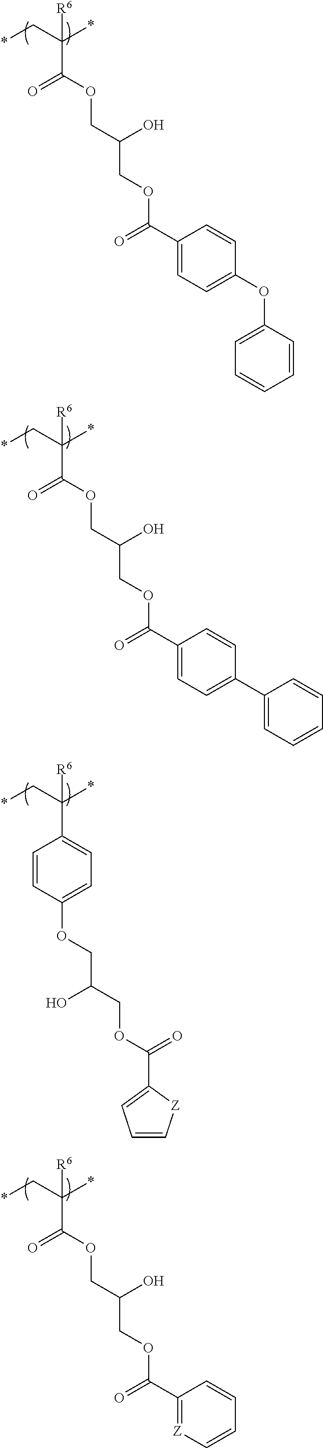

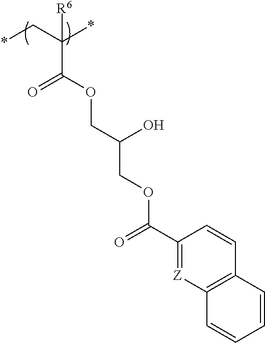

Preferred specific examples of the repeating unit represented by Formula (AD-3) include the following structures. However, the present invention is not limited thereto. In the following exemplified chemical formulae, R⁶'s each independently represent a hydrogen atom or an unsubstituted or substituted methyl group.

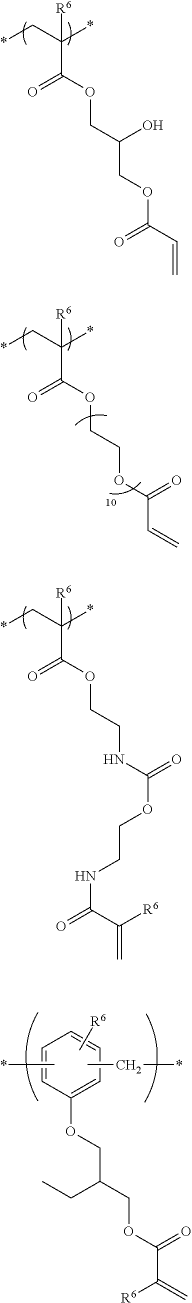

The resin can also include a repeating unit (hereinafter, also simply referred to as “other repeating units”) other than the repeating unit represented by any of Formulae (AD-1) to (AD-3). Such other repeating units include, for example, a repeating unit which does not contain an aromatic ring and a polymerizable group, a repeating unit which contains an aromatic ring in which a substituent bonded to the aromatic ring has a formula weight of more than 1000, or the like.

A proportion of the other repeating units is preferably 15% by mass with respect to all repeating units in the resin. As a result, the adhesiveness between the adhesive film and the carbon-containing support and the adhesiveness between the adhesive film and the composition for forming a pattern are further improved. The upper limit of the above-described numerical range is more preferably 10% by mass or less, still more preferably 5% by mass or less, and it is particularly preferable that the resin does not substantially contain the other repeating units. Here, the “does not substantially contain” means that the proportion of the other repeating units is less than 10% by mass with respect to all repeating units in the resin.

A content of the resin in the composition for forming an adhesive film is preferably 0.01% to 10% by mass. The upper limit of the above-described numerical range is preferably 5% by mass or less, more preferably 3% by mass or less, and still more preferably 1% by mass or less. In addition, the lower limit of the above-described numerical range is preferably 0.03% by mass or more, more preferably 0.05% by mass or more, and still more preferably 0.1% by mass or more. In the composition for forming an adhesive film, the content of the resin is preferably 70% by mass or more with respect to an amount of the total solid content. The lower limit of the above-described numerical range is more preferably 80% by mass or more, and still more preferably 90% by mass or more. In addition, it is practical that the upper limit of the above-described numerical range is 99% by mass or less. The resin may be a compound of one kind alone or a mixture of two or more kinds. In a case where the resin is a mixture, the total amount thereof is preferably within the above-described range.

<<Solvent>>

The composition for forming an adhesive film includes a solvent (hereinafter, may be referred to as a “solvent for an adhesive film”). The solvent is, for example, preferably a compound which is liquid at 23° C. and has a boiling point of 250° C. or lower. In general, the solid content other than the solvent finally forms an adhesive film. A content of the solvent for an adhesive film in the composition for forming an adhesive film is preferably 99.0% by mass or more and more preferably 99.5% by mass or more, and may be 99.6% by mass or more. By setting the proportion of the solvent within the above-described range, a film thickness during film formation is kept thin, which leads to the improvement in pattern formability during etching processing. In addition, it is practical that the content of the solvent for an adhesive film in the composition for forming an adhesive film is 99.99% by mass or less.

Only one kind or two or more kinds of the solvents may be contained in the composition for forming an adhesive film. In a case where two or more kinds thereof are contained, the total amount thereof is preferably within the above-described range.

A boiling point of the solvent for an adhesive film is preferably 230° C. or lower, more preferably 200° C. or lower, still more preferably 180° C. or lower, even more preferably 160° C. or lower, and even still more preferably 130° C. or lower. The lower limit value thereof is practically 23° C. but more practically 60° C. or higher. By setting the boiling point within the above-described range, the solvent can be easily removed from the adhesive film, which is preferable.

The solvent for an adhesive film is preferably an organic solvent. The solvent is preferably a solvent having any one or more of an alkylcarbonyl group, a carbonyl group, a hydroxyl group, or an ether group. Among these, it is preferable to use an aprotic polar solvent.

As specific examples thereof, alkoxy alcohol, propylene glycol monoalkyl ether carboxylate, propylene glycol monoalkyl ether, lactic acid ester, acetate, alkoxypropionic acid ester, chain-like ketone, cyclic ketone, lactone, and alkylene carbonate are selected.

Examples of the alkoxy alcohol include methoxyethanol, ethoxyethanol, methoxypropanol (for example, 1-methoxy-2-propanol), ethoxypropanol (for example, 1-ethoxy-2-propanol), propoxypropanol (for example, 1-propoxy-2-propanol), methoxybutanol (for example, 1-methoxy-2-butanol and 1-methoxy-3-butanol), ethoxybutanol (for example, 1-ethoxy-2-butanol and 1-ethoxy-3-butanol), and methylpentanol (for example, 4-methyl-2-pentanol).

As the propylene glycol monoalkyl ether carboxylate, at least one selected from the group consisting of propylene glycol monomethyl ether acetate, propylene glycol monomethyl ether propionate, and propylene glycol monoethyl ether acetate is preferable, and propylene glycol monomethyl ether acetate (PGMEA) is particularly preferable.

In addition, as the propylene glycol monoalkyl ether, propylene glycol monomethyl ether (PGME) or propylene glycol monoethyl ether is preferable.

As the lactic acid ester, ethyl lactate, butyl lactate, or propyl lactate is preferable.

As the acetate, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable.

As the alkoxypropionic acid ester, methyl 3-methoxypropionate (MMP) or ethyl 3-ethoxypropionate (EEP) is preferable.

As the chain-like ketone, 1-octanone, 2-octanone, 1-nonanone, 2-nonanone, acetone, 4-heptanone, 1-hexanone, 2-hexanone, diisobutyl ketone, phenylacetone, methyl ethyl ketone, methyl isobutyl ketone, acetylacetone, acetonylacetone, ionone, diacetonyl alcohol, acetylcarbinol, acetophenone, methyl naphthyl ketone, or methyl amyl ketone is preferable.

As the cyclic ketone, methylcyclohexanone, isophorone, or cyclohexanone is preferable.

As the lactone, γ-butyrolactone (γBL) is preferable.

As the alkylene carbonate, propylene carbonate is preferable.

In addition to the above-described solvents, an ester-based solvent having 7 or more (preferably 7 to 14, more preferably 7 to 12, and still more preferably 7 to 10) carbon atoms and having 2 or less heteroatoms is preferably used.

Preferred examples of the ester-based solvent having 7 or more carbon atoms and 2 or less heteroatoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is particularly preferably used.

Examples of a preferred solvent among the solvents for an adhesive film include alkoxy alcohol, propylene glycol monoalkyl ether carboxylate, propylene glycol monoalkyl ether, lactic acid ester, acetate, alkoxypropionic acid ester, chain-like ketone, cyclic ketone, lactone, and alkylene carbonate.

<<Other Components>>

The composition for forming an adhesive film may include one or more kinds of an alkylene glycol compound, a polymerization initiator, a polymerization inhibitor, an antioxidant, a leveling agent, a thickener, a surfactant, or the like, in addition to the above-described components.

<<<Alkylene Glycol Compound>>>

The composition for forming an adhesive film may include an alkylene glycol compound. In the alkylene glycol compound, the number of alkylene glycol repeating units is preferably 3 to 1000, more preferably 4 to 500, still more preferably 5 to 100, and even more preferably 5 to 50. A weight-average molecular weight (Mw) of the alkylene glycol compound is preferably 150 to 10000, more preferably 200 to 5000, still more preferably 300 to 3000, and even more preferably 300 to 1000.

Examples of the alkylene glycol compound include polyethylene glycol, polypropylene glycol, mono- or di-methyl ether thereof, mono- or di-octyl ether, mono- or di-nonyl ether, mono- or di-decyl ether, monostearic acid ester, monooleic acid ester, monoadipic acid ester, and monosuccinic acid ester, and polyethylene glycol or polypropylene glycol is preferable.

Surface tension of the alkylene glycol compound at 23° C. is preferably 38.0 mN/m or more and more preferably 40.0 mN/m or more. The upper limit of the surface tension is not particularly specified, but is, for example, 48.0 mN/m or less. By formulating such a compound, wettability of the composition for forming a pattern provided immediately above the adhesive film can be further improved.

The surface tension is measured at 23° C. using a surface tensiometer SURFACE TENS-IOMETER CBVP-A3 manufactured by Kyowa Interface Science Co., LTD. and a glass plate. The unit is mN/m. Two samples are produced for one level and are respectively measured three times. An arithmetic mean value of a total of six times is adopted as an evaluation value.

A content of the alkylene glycol compound is 40% by mass or less, preferably 30% by mass or less, more preferably 20% by mass or less, and still more preferably 1% to 15% by mass, with respect to the amount of the total solid content. The alkylene glycol compound may be used alone or in combination of two or more kinds thereof. In a case where two or more kinds thereof are used, the total amount thereof is preferably within the above-described range.

<<<Polymerization Initiator>>>

The composition for forming an adhesive film may include a polymerization initiator and preferably includes at least one kind of a thermal polymerization initiator or a photopolymerization initiator. By including the polymerization initiator, a reaction of the polymerizable group included in the composition for forming an adhesive film is promoted, and thus the adhesiveness is improved. From the viewpoint that crosslinking reactivity with the composition for forming a pattern is improved, a photopolymerization initiator is preferable. As the photopolymerization initiator, a radical polymerization initiator and a cationic polymerization initiator are preferable, and a radical polymerization initiator is more preferable. In addition, in the present invention, a plurality of kinds of photopolymerization initiators may be used in combination.

As the thermal polymerization initiator, the respective components described in JP2013-036027A, JP2014-090133A, and JP2013-189537A can be used. Also regarding the content or the like, reference can be made to the description in the above-described publications.

As a radical polymerization initiator, known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound such as acylphosphine oxide, hexaarylbiimidazole, an oxime compound such as an oxime derivative, an organic peroxide, a thio compound, a ketone compound, an aromatic onium salt, ketoxime ether, an aminoacetophenone compound, hydroxyacetophenone, an azo-based compound, an azide compound, a metallocene compound, an organic boron compound, and an iron arene complex. For the details thereof, reference can be made to the description in paragraphs 0165 to 0182 of JP2016-027357A, the contents of which are incorporated in the present specification.

Examples of the acylphosphine compound include 2,4,6-trimethylbenzoyl-diphenyl-phosphine oxide. In addition, IRGACURE-819, IRGACURE 1173, and IRGACURE-TPO (trade names: all are manufactured by BASF SE), which are commercially available products, can be used.

In a case where the photopolymerization initiator used in the composition for forming an adhesive film is formulated, a content thereof in the total solid content is, for example, 0.0001% to 5% by mass, preferably 0.0005% to 3% by mass, and more preferably 0.01% to 10% by mass. In a case where two or more kinds of photopolymerization initiators are used, the total amount thereof is preferably within the above range.

<Method for Producing Composition for Forming Adhesive Film>

The composition for forming an adhesive film according to the embodiment of the present invention is prepared by formulating raw materials in a predetermined proportion. The raw materials refer to components which are actively formulated in the composition for forming an adhesive film, and in which unintentionally contained components such as impurities are excluded. Specifically, a curable component and a solvent are exemplified. Here, the raw materials may be commercially available products or synthetic products. All the raw materials may contain impurities such as metal particles.

As one preferred embodiment of a method for producing the composition for forming an adhesive film according to the embodiment of the present invention, a producing method including subjecting at least one kind of raw materials contained in the composition for forming an adhesive film to a filtration treatment with a filter can be mentioned. In addition, it is also preferable that two or more kinds of raw materials are mixed, then filtered with a filter, and mixed with other raw materials (may or may not be filtered). As one more preferred embodiment thereof, an embodiment in which raw materials (preferably, all raw materials) contained in the composition for forming an adhesive film are mixed, and then subjected to a filtration treatment with a filter is exemplified.

<Laminate>

The laminate according to an embodiment of the present invention includes a carbon-containing support and an adhesive film which is formed from the above-described composition for forming an adhesive film and is provided in contact with the carbon-containing support. This laminate may include other layers on the adhesive film. Such a layer is, for example, a composition layer for forming a pattern, which is formed by applying a composition for forming a pattern onto the adhesive film. In addition, a method for manufacturing the laminate according to the embodiment of the present invention includes applying the above-described composition for forming an adhesive film onto the carbon-containing support to form an adhesive film. A method of forming the adhesive film will be described later.

In the carbon-containing support, from the viewpoint of improving durability as a hard mask material, and the like, the above-described proportion of carbon atoms in the depth region of 10 nm from the surface (proportion of carbon atoms to total atoms excluding hydrogen atoms) is preferably 60% or more, more preferably 70% or more, still more preferably 80% or more, and particularly preferably 90% or more. The upper limit of the carbon content is not particularly limited, but is practically 99% or less, and may be 95% or less or 90% or less.

For example, the carbon-containing support can be produced by forming, on a semiconductor substrate, a carbon film such as a spin-on carbon (SOC) film, a diamond-like carbon (DLC) film, and other amorphous carbon films.

The SOC film can be formed, for example, by applying a composition in which a carbonaceous material is dissolved in an organic solvent onto a substrate by a spin coating method or the like, and drying the composition. As such a carbonaceous material, for example, a carbon-rich compound containing 80% by mass or more of carbon with respect to the total molecular weight of the compound can be used. As such a carbon-rich compound, for example, a copolymer having a nortricylene skeleton, a copolymer of phenol and dicyclopentadiene, a copolymer of naphthol and dicyclopentadiene, a copolymer of acenaphthylene and a polymerizable monomer having a hydroxyl group (for example, hydroxystyrene and the like), a copolymer of indene and a polymerizable monomer having a hydroxyl group, a polymer of hydroxyvinylnaphthalene, a polymer of tricyclopentadiene, a hydrogenated naphthol novolac resin, a bisphenol compound (for example, fluorene bisphenol and the like) and a novolac resin thereof, an adamantandiyldiphenol compound and a novolac resin thereof, a bisnaphthol compound and a novolac resin thereof, and fullerene having a phenol group. For details of these materials, for example, JP2005-128509A, JP2005-250434A, JP2006-227391A, and JP2007-199653A can be referred to. In addition, for an example of the SOC film, the description in paragraph 0126 of JP2011-164345A can be referred to. The contents of these references are incorporated in the present specification.

In addition, a commercially available product can also be used as the carbonaceous material which can be applied.

On the other hand, the DLC film and other amorphous carbon films can be formed, for example, by a physical vapor deposition (PVD) method using a carbon raw material such as graphite or a chemical vapor deposition (CVD) method using a hydrocarbon gas such as acetylene.

In the carbon film, the proportion of carbon atoms to total atoms excluding hydrogen atoms is preferably 50% or more. The lower limit of the proportion is more preferably 60% or more, still more preferably 70% or more, and particularly preferably 80% or more. The upper limit of the proportion is not particularly limited, but is practically 99% or less, and may be 95% or less or 90% or less. The carbon content in the carbon film is preferably 60% by mass more, more preferably 70% by mass or more, and still more preferably 80% by mass or more. The upper limit of the carbon content is not particularly limited, but is practically 99% by mass or less, and may be 95% by mass or less or 90% by mass or less. A thickness of the carbon film is preferably 50 to 300 nm. The upper limit of the above-described numerical range is preferably 290 nm or less, more preferably 275 nm or less, and still more preferably 200 nm or less. In addition, the lower limit of the above-described numerical range is preferably 60 nm or more, more preferably 75 nm or more, and still more preferably 100 nm or more. By adjusting the carbon content, thickness, and film density of the carbon film as described above, or by adjusting a surface density of an island-shaped film in a case where the carbon film is formed extremely thin, the carbon content on the surface of the carbon-containing support can be adjusted.

A material of the semiconductor substrate is not particularly limited, and is, for example, silicon, glass, quartz, sapphire, silicon carbide, gallium nitride, aluminum, amorphous aluminum oxide, polycrystalline aluminum oxide, silicon nitride, silicon oxynitride, GaAsP, GaP, AlGaAs, InGaN, GaN, AlGaN, ZnSe, AlGa, InP, and ZNo. Specific examples of glass materials include aluminosilicate glass, aluminoborosilicate glass, and barium borosilicate glass.

<<Physical Property Value or the Like>>

A film density of the adhesive film formed from the above-described composition for forming an adhesive film is preferably 0.90 to 1.60 g/cm³. As a result, in a case where the mold is pressed against the composition for forming a pattern, gas existing between the mold and the composition for forming a pattern is easily absorbed by the adhesive film, and bubble defects of the pattern (regions in which the composition for forming a pattern is not filled) are suppressed. The upper limit of the numerical range is more preferably 1.50 g/cm³ or less, and still more preferably 1.30 g/cm³ or less. In addition, the lower limit of the numerical range is more preferably 0.95 g/cm³ or more, and still more preferably 1.00 g/cm³ or more.

In the adhesive film formed from the above-described composition for forming an adhesive film according to the embodiment of the present invention, a surface free energy γₐ obtained by Expression (1) is preferably 30 to 70 mJ/m². As a result, the adhesiveness between the adhesive film and the carbon-containing support is further improved. In addition, the wettability of the composition for forming a pattern, which is applied onto the adhesive film, is also improved. The upper limit of the numerical range is more preferably 65 mJ/m² or less and still more preferably 60 mJ/m² or less. In addition, the lower limit of the numerical range is more preferably 35 mJ/m² or more and still more preferably 40 mJ/m² or more.

$${γ}_{a} = {γ}_{a}^{d} + {γ}_{a}^{p} \qquad Expression ( 1 )$$

In Expression (1), γₐ^{d} and γₐ^{p} each represent a dispersion component and a polar component of the surface free energy of a surface of the adhesive film, which are derived based on Kaelbel-Uy theory.

To measure the surface free energy, first, a plurality of types of solvents having known dispersion component and polar component of surface free energy are dropped onto an adhesive film formed on a substrate such as a glass plate, and a contact angle of each solvent is measured. Next, γₐ is obtained by applying each of the measured contact angles to Expression (1-2) and solving simultaneous equations relating to γₐ^{d} and γₐ^{p} of the adhesive film.

$${γ}_{L} ( 1 - cos θ ) = 2 √ ( {γ}_{a}^{d} {γ}_{L}^{d} ) + 2 √ ( {γ}_{a}^{p} {γ}_{L}^{p} ) \qquad Expression ( 1 \text{-} 2 )$$

In Expression (1-2), θ represents a contact angle of a solvent on the adhesive film, γ_{L} represents a surface free energy (mJ/m²) of the solvent, γ_{L}^{d} represents a dispersion component of the surface free energy of the solvent, γ_{L}^{p} represents a polar component of the surface free energy of the solvent, and γ_{L}=γ_{L}^{d}+γ_{L}^{p} is satisfied.

For the measurement of the contact angle, for example, a fully automatic contact angle meter DMo-901 (manufactured by Kyowa Interface Science Co., Ltd.) can be used. In the measurement of the surface free energy, the atmosphere is, for example, under atmospheric pressure, and the temperature is, for example, 23° C. In addition, in applying the Kaelbel-Uy theory, as a solvent having known dispersion component and polar component of surface free energy, water, diiodomethane, formamide, oleic acid, and n-hexadecane can be used. In order to obtain the surface free energy of a solid surface based on the Kaelbel-Uy theory, at least two types of solvents are required, but in the present invention, a combination of water and diiodomethane is preferentially adopted. In a case where there is a solvent for which it is impossible or impractical to measure the contact angle for some reason, the corresponding solvent is changed to a solvent which can be practically measured. The solvent adopted by the modification is sequentially selected from formamide, oleic acid, and n-hexadecane in order of priority. The priority of these solvents is formamide>oleic acid>n-hexadecane. For details of the Kaelbel-Uy theory, for example, Journal of the Adhesion Society of Japan, Vol. 52, No. 6 (2016), pp. 171 to 175 can be referred to, the content of which is incorporated in the present specification.

Furthermore, in the laminate according to the embodiment of the present invention, a surface free energy γ_{ab} at an interface between the carbon-containing support and the adhesive film, which is obtained by Expression (2), is preferably 5.0 mJ/m² or less. As a result, the adhesiveness between the adhesive film and the carbon-containing support is further improved. The upper limit of the numerical range is more preferably 4.0 mJ/m² or less and still more preferably 2.0 mJ/m² or less. In addition, the lower limit of the numerical range is not particularly limited, but is practically 0.1 mJ/m² or more and may be 0.3 mJ/m² or more.

$${γ}_{a b} = {( √ {γ}_{a}^{d} - √ {γ}_{b}^{d} )}^{2} + {( √ {γ}_{a}^{p} - √ {γ}_{b}^{p} )}^{2} \qquad Expression ( 2 )$$

In Expression (2), γₐ^{d} and γₐ^{p} each represent a dispersion component and a polar component of a surface free energy of a surface (surface in a case of being alone) of the adhesive film, which are derived based on Kaelbel-Uy theory, and γ_{b}^{d} and γ_{b}^{p} each represent a dispersion component and a polar component of a surface free energy of a surface (surface in a case of being alone) of the carbon-containing support, which are derived based on Kaelbel-Uy theory.

<Composition for Forming Pattern>

The composition for forming an adhesive film according to the embodiment of the present invention is usually used as a composition for forming an adhesive film for the composition for forming a pattern. Composition or the like of the composition for forming a pattern is not particularly specified, but the composition for forming a pattern preferably includes a polymerizable compound.

<<Polymerizable Compound>>

The composition for forming a pattern preferably includes a polymerizable compound, and it is more preferable that the polymerizable compound constitutes the maximum-amount component. The polymerizable compound may have one polymerizable group or two or more polymerizable groups in one molecule. At least one kind of polymerizable compounds included in the composition for forming a pattern preferably has two to five polymerizable groups, more preferably has two to four polymerizable groups, still more preferably has two or three polymerizable groups, and even more preferably has three polymerizable groups, in one molecule. The polymerizable compound in the composition for forming a pattern preferably has the same kind of polymerizable group as the polymerizable group of a resin in the composition for forming an adhesive film. As a result, a crosslinkable monomer can be bonded to the polymerizable compound in the composition for forming a pattern, and due to a bond across an interface between the compositions, an effect of further improving the adhesiveness at the interface can be achieved.

At least one kind of polymerizable compounds included in the composition for forming a pattern preferably has a cyclic structure. Examples of this cyclic structure include an aliphatic hydrocarbon ring Cf and an aromatic hydrocarbon ring Cr. Among these, the polymerizable compound preferably has the aromatic hydrocarbon ring Cr and more preferably has a benzene ring.

A molecular weight of the polymerizable compound is preferably 100 to 900.

The at least one kind of polymerizable compounds is preferably represented by Formula (I-1).

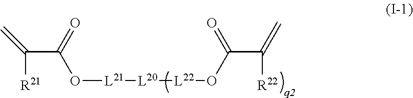

L²⁰ is a (1+q2)-valent linking group, and examples thereof include a linking group having a cyclic structure. Examples of the cyclic structure include examples of the ring Cf, the ring Cr, the ring Cn, the ring Co, and the ring Cs.

R²¹ and R²² each independently represent a hydrogen atom or a methyl group. L²¹ and L²² each independently represent a single bond or the linking group L. L²⁰ and L²¹ or L²² may be bonded to each other via or without via the linking group L to form a ring. L²⁰, L²¹, and L²² may have the substituent T. A plurality of substituents T may be bonded to each other to form a ring. In a case where there are a plurality of substituents T, the plurality of substituents T may be the same or different from each other.

q2 is an integer of 0 to 5, preferably an integer of 0 to 3, more preferably an integer of 0 to 2, and still more preferably 0 or 1.

Examples of the polymerizable compound include compounds used in the following Examples, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A, but the present invention is not construed as being limited thereto.

The content of the polymerizable compound in the composition for forming a pattern is preferably 30% by mass or more, more preferably 45% by mass or more, still more preferably 50% by mass or more, and even more preferably 55% by mass or more, and may be 60% by mass or more or further 70% by mass or more. In addition, the upper limit value thereof is preferably less than 99% by mass and more preferably 98% by mass or less, and can also be 97% by mass or less.

It is preferable that the boiling point of the polymerizable compound is set based on a relationship with the high-molecular-weight compound included in the above-described composition for forming an adhesive film and designed for formulation. The boiling point of the polymerizable compound is preferably 500° C. or lower, more preferably 450° C. or lower, and still more preferably 400° C. or lower. The lower limit value thereof is preferably 200° C. or higher, more preferably 220° C. or higher, and still more preferably 240° C. or higher.

<<Other Components>>

The composition for forming a pattern may contain an additive other than the polymerizable compound. A polymerization initiator, a solvent, a surfactant, a sensitizer, a release agent, an antioxidant, a polymerization inhibitor, and the like may be contained as other additives.

In the present invention, a content of the solvent in the composition for forming a pattern is preferably 5% by mass or less, more preferably 3% by mass or less, and still more preferably 10% by mass or less, with respect to the composition for forming a pattern.

The composition for forming a pattern can also adopt an aspect in which a polymer (which has preferably a weight-average molecular weight of more than 1000 and more preferably a weight-average molecular weight of more than 2000) is not substantially contained. The expression “polymer is not substantially contained” means, for example, that the content of the polymer is 0.01% by mass or less with respect to the composition for forming a pattern, and it is preferable that the content thereof is 0.005% by mass or less and it is more preferable that the polymer is not contained at all.

In addition, specific examples of the composition for forming a pattern, which can be used together with the composition for forming an adhesive film according to the embodiment of the present invention, include the compositions described in JP2013-036027A, JP2014-090133A, and JP2013-189537A, the contents of which are incorporated in the present specification. In addition, also regarding preparation of the composition for forming a pattern and a pattern producing method, reference can be made to the descriptions in the above-described publications, the contents of which are incorporated in the present specification.

<<Physical Property Value or the Like>>

A viscosity of the composition for forming a pattern is preferably 20.0 mPa·s or less, more preferably 15.0 mPa·s or less, still more preferably 11.0 mPa·s or less, and even more preferably 9.0 mPa·s or less. The lower limit value of the viscosity is not particularly limited, but can be, for example, 5.0 mPa·s or more. The viscosity is measured according to the following method.

The viscosity is measured using an E-type rotational viscometer RE85L manufactured by TOKI SANGYO CO., LTD. and a standard cone rotor (1° 34′×R²⁴) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

Surface tension (γResist) of the composition for forming a pattern is preferably 28.0 mN/m or more and more preferably 30.0 mN/m or more, and may be 32.0 mN/m or more. By using the composition for forming a pattern which has high surface tension, a capillary force is increased and thus high-speed filling of a mold pattern with the composition for forming a pattern is possible. The upper limit value of the surface tension is not particularly limited, but from the viewpoints of a relationship with the adhesive film and imparting ink jet suitability, is preferably 40.0 mN/m or less and more preferably 38.0 mN/m or less, and may be 36.0 mN/m or less.

The surface tension of the composition for forming a pattern is measured according to the same method as the measuring method for the alkylene glycol compound.

An Ohnishi parameter of the composition for forming a pattern is preferably 5.0 or less, more preferably 4.0 or less, and still more preferably 3.7 or less. The lower limit value of the Ohnishi parameter of the composition for forming a pattern is not particularly specified, but may be, for example, 1.0 or more or further 2.0 or more. For the solid contents in the composition for forming a pattern, the Ohnishi parameter of the composition for forming a pattern can be determined by substituting the number of carbon atoms, the number of hydrogen atoms, and the number of oxygen atoms in all the constituent components into the following expression.

Ohnishi parameter=Sum of number of carbon atoms, number of hydrogen atoms, and number of oxygen atoms/(Number of carbon atoms−Number of oxygen atoms)

<Storage Container>

As a storage container of the composition for forming an adhesive film and the composition for forming a pattern, which are used in the present invention, storage containers known in the related art can be used. In addition, as the storage container, for the purpose of suppressing impurities from being infiltrated into a raw material or a composition, a multilayer bottle having a container interior wall made of six layers of six kinds of resins or a bottle having a seven-layer structure of six kinds of resins is also preferably used. Examples of such a container include the container described in JP2015-123351A.

<Kit for Imprinting>

A kit for imprinting includes a combination of the composition for forming a pattern, which is for forming a pattern (cured film with a transferred pattern) by the imprinting method, and a composition for forming an adhesive film, which is for forming an adhesive film. For example, the composition for forming a pattern and the composition for forming an adhesive film are each stored in separate storage containers, and combined. By using such a kit, an adhesive film having excellent adhesive force can be formed, and as a result, it is possible to perform imprinting which can efficiently form a pattern with high quality.

<Pattern Producing Method>

A pattern producing method according to an embodiment of the present invention includes applying a composition for forming a pattern onto the adhesive film obtained by the above-described method for manufacturing a laminate, curing the composition for forming a pattern in a state of being in contact with a mold, and peeling off the mold from the composition for forming a pattern. More specifically, a pattern (cured film with a transferred pattern) producing method according to a preferred embodiment of the present invention includes: a step (adhesive film formation step) of forming an adhesive film on a surface of a carbon-containing support (hereinafter, also simply referred to as a “substrate”) using the composition for forming an adhesive film according to the embodiment of the present invention; a step (step of forming composition layer for forming a pattern) of applying the composition for forming a pattern onto the adhesive film (preferably, a surface of the adhesive film) to form a composition layer for forming a pattern; a mold contact step of bringing a mold into contact with the composition layer for forming a pattern; a light irradiation step of exposing the composition layer for forming a pattern in a state of being in contact with the mold; and a release step of peeling off the mold from the exposed composition layer for forming a pattern.

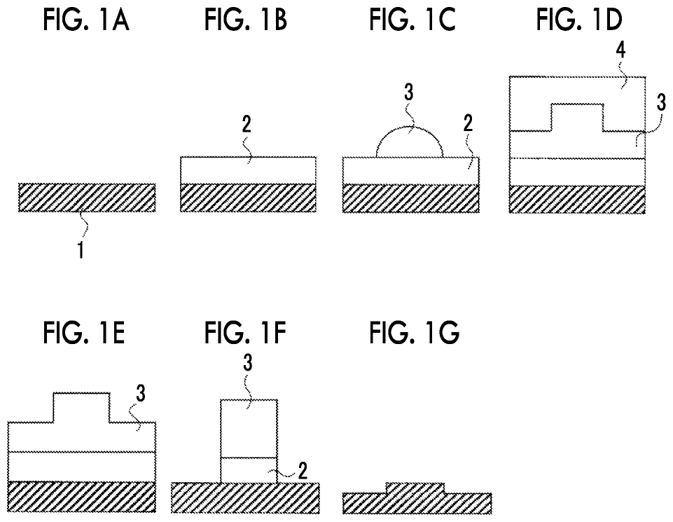

Hereinafter, the pattern producing method will be described with reference to FIGS. 1A to 1G. It goes without saying that the configuration of the present invention is not limited by the drawings.

<<Adhesive Film Formation Step>>

In the adhesive film formation step, as shown in FIGS. 1A and 1i, an adhesive film 2 is formed on a surface of a substrate 1. The adhesive film is preferably formed by applying the composition for forming an adhesive film in a layer form onto the substrate.

A method for applying the composition for forming an adhesive film onto the surface of the substrate is not particularly specified, and generally known application methods can be adopted. Specific examples of the application method include a dip coating method, an air knife coating method, a curtain coating method, a wire bar coating method, a gravure coating method, an extrusion coating method, a spin coating method, a slit scanning method, and an ink jet method, and a spin coating method is preferable.

In addition, after the composition for forming an adhesive film is applied in a layer form onto the substrate, preferably, the solvent is volatilized (dried) by heat to form an adhesive film which is a thin film.

A thickness of the adhesive film 2 is preferably 2 nm or more, more preferably 3 nm or more, and still more preferably 4 nm or more. In addition, the thickness of the adhesive film is preferably 20 nm or less, more preferably 10 nm or less, and still more preferably 7 nm or less. By setting the film thickness to be equal to or greater than the above-described lower limit value, extendability (wettability) of the composition for forming a pattern on the adhesive film is improved, and a uniform residual film can be formed after imprinting. By setting the film thickness to be equal to or less than the above-described upper limit value, the thickness of the residual film after imprinting is reduced, the film thickness unevenness is less likely to occur, and thus uniformity of the residual film is improved.

<<Step of Forming Composition Layer for Forming Pattern>>

In this step, for example, as shown in FIG. 1C, a composition 3 for forming a pattern is applied onto the surface of the adhesive film 2.

A method for applying the composition for forming a pattern is not particularly specified, and reference can be made to the description in paragraph 0102 of JP2010-109092A (the publication number of the corresponding US application is US2011/183127A), the contents of which are incorporated in the present specification. The composition for forming a pattern is preferably applied onto the surface of the adhesive film by an ink jet method. In addition, the composition for forming a pattern may be applied through multiple applying. In a method for arranging liquid droplets on the surface of the adhesive film by the ink jet method or the like, an amount of the liquid droplets is preferably approximately 1 to 20 pL, and the liquid droplets are preferably arranged on the surface of the adhesive film at an interval between liquid droplets. The interval between liquid droplets is preferably an interval of 10 to 1000 μm. In a case of the ink jet method, the interval between liquid droplets is an arrangement interval between ink jet nozzles.

Furthermore, a volume ratio of the adhesive film 2 to the film-like composition 3 for forming a pattern applied onto the adhesive film is preferably 1:1 to 500, more preferably 1:10 to 300, and still more preferably 1:50 to 200.

In addition, the method for manufacturing a laminate is a manufacturing method using the above-described kit, and may include applying the composition for forming a pattern onto a surface of an adhesive film formed of the above-described composition for forming an adhesive film. Furthermore, it is preferable that the method for manufacturing a laminate includes a step of applying the above-described composition for forming an adhesive film in a layer form onto a substrate, and includes heating (baking) the composition for forming an adhesive film, which has been applied in a layer form, preferably at 100° C. to 300° C., more preferably at 130° C. to 260° C., and still more preferably at 150° C. to 230° C. A heating time is preferably 30 seconds to 5 minutes.

In a case where the composition for forming a pattern is applied to the adhesive film, an aspect in which a liquid film is formed on the substrate may be adopted. The liquid film may be formed by a conventional method. For example, the liquid film may be formed by applying, onto a substrate, a composition containing a crosslinkable monomer (examples thereof include examples of the polymerizable compound), which is a liquid at 23° C., and the like.

<<Mold Contact Step>>

In the mold contact step, for example, as shown in FIG. 1D, the composition 3 for forming a pattern is brought into contact with a mold 4 having a pattern for transferring a pattern shape. Through such a step, a desired pattern (imprint pattern) is obtained.

Specifically, in order to transfer a desired pattern to the film-like composition for forming a pattern, the mold 4 is brought into press contact with the surface of the film-like composition 3 for forming a pattern.

The mold may be a light-transmitting mold or a non-light-transmitting mold. In a case where the light-transmitting mold is used, it is preferable that the composition 3 for forming a pattern is irradiated with light from a mold side. In the present invention, it is more preferable that the light-transmitting mold is used and light is irradiated from the mold side.

The mold, which can be used in the present invention, is a mold having a pattern to be transferred. The pattern of the mold can be formed according to a desired processing accuracy, for example, by photolithography, an electron beam drawing method, or the like, but in the present invention, a mold pattern forming method is not particularly limited. In addition, a pattern formed by the pattern producing method according to the preferred embodiment of the present invention can also be used as a mold.

A material constituting the light-transmitting mold used in the present invention is not particularly limited, but examples thereof include glass, quartz, a light-transmitting resin such as polymethyl methacrylate (PMMA) and a polycarbonate resin, a transparent metal vapor-deposited film, a flexible film such as polydimethylsiloxane, a photocured film, and a metal film, and quartz is preferable.

A non-light-transmission-type mold material used in a case where a light-transmitting substrate is used in the present invention is not particularly limited, but may be any material having a predetermined strength. Specific examples thereof include a ceramic material, a vapor-deposited film, a magnetic film, a reflective film, a substrate made of a metal such as Ni, Cu, Cr, and Fe, and a substrate made of SiC, silicon, silicon nitride, polysilicon, silicon oxide, or amorphous silicon, but there is no particular restriction.

In the pattern producing method, in a case where imprint lithography is performed using the composition for forming a pattern, mold pressure is preferably set to 10 atm or lower. By setting the mold pressure to 10 atm or less, the mold or the substrate is less likely to be deformed and thus the pattern accuracy is improved. In addition, from the viewpoint that a device tends to be reduced in size due to low pressure, the above-described range is preferable. The mold pressure is preferably selected from a range in which uniformity of mold transfer can be ensured while the residual film of the composition for forming a pattern corresponding to a projection part of the mold is reduced.

In addition, it is also preferable that the contact between the composition for forming a pattern and the mold is performed under an atmosphere containing a helium gas, a condensable gas, or both a helium gas and a condensable gas.

<<Light Irradiation Step>>

In the light irradiation step, the exposure was performed by irradiating the composition for forming a pattern with light, to form a cured substance. An irradiation amount of light irradiation in the light irradiation step may be sufficiently larger than the minimum irradiation amount required for curing. The irradiation amount required for curing is appropriately determined by examining consumption of an unsaturated bond of the composition for forming a pattern or the like. A kind of light to be radiated is not particularly specified, but ultraviolet light is exemplified.

In addition, in the imprint lithography applied to the present invention, a temperature of the substrate during light irradiation is usually room temperature, but in order to increase reactivity, light irradiation may be performed while heating. Since setting a vacuum state as a stage prior to the light irradiation is effective in preventing air bubbles from being mixed, suppressing a decrease in reactivity due to oxygen mixing, and improving adhesiveness between the mold and the composition for forming a pattern, the light irradiation may be performed in a vacuum state. In addition, in the pattern producing method, a preferred degree of vacuum during the light irradiation is in a range of 10⁻¹ Pa to normal pressure.

During the exposure, exposure illuminance is preferably in a range of 1 to 500 mW/cm² and more preferably in a range of 10 to 400 mW/cm². An exposure time is not particularly limited, but is preferably 0.01 to 10 seconds and more preferably 0.5 to 1 second. An exposure amount is preferably in a range of 5 to 1000 mJ/cm² and more preferably in a range of 10 to 500 mJ/cm².

In the pattern producing method, after the film-like composition for forming a pattern (composition layer for forming a pattern) is cured by the light irradiation, as necessary, a step of applying heat to the cured pattern to further cure the pattern may be included. A temperature for heating and curing the composition for forming a pattern after the light irradiation is preferably 150° C. to 280° C. and more preferably 200° C. to 250° C. In addition, a time for applying heat is preferably 5 to 60 minutes and more preferably 15 to 45 minutes.

In a case where the composition for forming an adhesive film according to the embodiment of the present invention is used, due to the above-described light irradiation or heating, the crosslinking reaction between the polymerizable group of the high-molecular-weight compound in the adhesive film and the crosslinkable group of the crosslinkable monomer is promoted. In addition, some of the crosslinkable groups of the crosslinkable monomer may also undergo the crosslinking reaction with the polymerizable compound in the composition for forming a pattern provided on the adhesive film, and the present invention also has an effect of further improving the adhesiveness at an interface between the compositions due to a bond across the interface, in addition to the effect of improving the film hardness of the adhesive film. In the imprint lithography, a temperature of the substrate during light irradiation is usually room temperature, but in order to increase reactivity, light irradiation may be performed while heating. Since setting a vacuum state as a stage prior to the light irradiation is effective in preventing air bubbles from being mixed, suppressing a decrease in reactivity due to oxygen mixing, and improving adhesiveness between the mold and the composition for forming a pattern, the light irradiation may be performed in a vacuum state. In addition, in the pattern producing method, a preferred degree of vacuum during the light irradiation is in a range of 10⁻¹ Pa to normal pressure.

<<Release Step>>

In the release step, the cured substance and the mold are separated from each other (FIG. 1E). The obtained pattern can be used for various uses as described later. That is, the present invention discloses a laminate further having the pattern formed of the composition for forming a pattern, on the surface of the adhesive film. In addition, a film thickness of the composition layer for forming a pattern, consisting of the composition for forming a pattern used in the present invention, varies depending on intended uses, but is approximately 0.01 μm to 30 μm. Furthermore, as will be described later, etching or the like can also be performed.

<Pattern and Application Thereof>

The pattern formed by the pattern producing method can be used as a permanent film used in a liquid crystal display device (LCD) or the like, or an etching resist (mask for lithography) for manufacturing a semiconductor element. In particular, the present specification discloses a method for manufacturing a semiconductor device, which manufactures a semiconductor element using the pattern according to the preferred embodiment of the present invention. The method for manufacturing a semiconductor element according to the preferred embodiment of the present invention may further include a step of performing etching or ion implantation on the substrate using the pattern obtained by the pattern producing method as a mask and a step of forming an electronic member. The above-described semiconductor element is preferably a semiconductor element. That is, the present specification discloses a method for manufacturing a semiconductor element, which includes the pattern producing method. Furthermore, the present specification discloses a method for manufacturing an electronic apparatus, which includes a step of obtaining a semiconductor element by the above-described method for manufacturing a semiconductor element and a step of connecting the semiconductor element and a control mechanism for controlling the semiconductor element.

In addition, a grid pattern is formed on a glass substrate of the liquid crystal display device using the pattern formed by the pattern producing method, and thus a polarizing plate having low reflection or absorption and a large screen size (for example, 55 inches or 60 inches (1 inch is 2.54 centimeters)) can be manufactured at low cost. For example, the polarizing plate described in JP2015-132825A or WO2011/132649A can be manufactured.

The pattern formed in the present invention is also useful as an etching resist (mask for lithography) as shown in FIGS. 1F and 1G. In a case where the pattern is used as an etching resist, first, a fine pattern of, for example, a nano or micron order is formed on the substrate by the pattern producing method. In the present invention, the pattern producing method is particularly advantageous in that a fine pattern of a nano order can be formed, and a pattern having a size of 50 nm or less and particularly 30 nm or less can also be formed. The lower limit value of the size of the pattern formed by the pattern producing method is not particularly specified, but can be, for example, 1 nm or more.

In addition, the pattern producing method according to the embodiment of the present invention can also be applied to a method for manufacturing a mold for imprinting. The method for manufacturing a mold for imprinting includes, for example, a step of producing a pattern on a substrate (for example, a substrate consisting of a transparent material such as quartz), which is used as a material for a mold, by the above-described pattern producing method, and a step of performing etching on the substrate using the pattern.

By performing etching with an etchant such as hydrogen fluoride in a case where wet etching is used as the etching method, or with an etching gas such as CF₄ in a case where dry etching is used, a desired pattern can be formed on the substrate. The pattern has favorable etching resistance particularly to dry etching. That is, the pattern formed by the pattern producing method is preferably used as a mask for lithography.

Specifically, the pattern formed in the present invention can be preferably used for producing a recording medium such as a magnetic disc, a light-receiving element such as a solid-state imaging element, a light emitting element such as a light emitting diode (LED) and organic electroluminescence (organic EL), an optical device such as a liquid crystal display device (LCD), an optical component such as a diffraction grating, a relief hologram, an optical waveguide, an optical filter, and a microlens array, a member for flat panel display such as a thin film transistor, an organic transistor, a color filter, an antireflection film, a polarizing plate, a polarizing element, an optical film, and a column material, a nanobiodevice, an immunoassay chip, a deoxyribonucleic acid (DNA) separation chip, a microreactor, a photonic liquid crystal, or a guide pattern for fine pattern formation (directed self-assembly, DSA) using self-assembly of block copolymers.

### EXAMPLES

Hereinafter, the present invention will be described in more detail with reference to Examples. The materials, the used amounts, the proportions, the treatment details, the treatment procedures, and the like shown in the following Examples can be appropriately modified without departing from the spirit of the present invention. Therefore, the scope of the present invention is not limited to the specific examples described below. Unless otherwise specified, “parts” and “%” are based on mass.

<Preparation of Composition for Forming Adhesive Film>

Resins shown in Tables 1 and 2 below were dissolved in a solvent and stirred well. Next, the mixture was filtered with a nylon filter having a pore diameter of 0.02 μm and a polytetrafluoroethylene (PTFE) filter having a pore diameter of 0.001 μm to prepare compositions for forming an adhesive film of Examples and Comparative Examples. A concentration of solid contents of the composition for forming an adhesive film was 0.3% by mass.

TABLE 1

| | Composition for forming | | Adhesive film | | Laminate | | Composition | Evaluation | |
|---|---|---|---|---|---|---|---|---|---|
| | adhesive film | | Film density | γₐ | | γ_{ab} | for forming | Peeling | Bubble |
| | Resin | Solvent | [g/cm³] | [mJ/m²] | Substrate | [mJ/m²] | pattern | defects | defects |
| Example 1 | P-1 | PGMEA | 1.08 | 52 | SOC1 | 2.0 | V-1 | A | A |
| Example 2 | P-2 | PGMEA | 0.97 | 46 | SOC1 | 1.0 | V-1 | C | A |
| Example 3 | P-3 | PGMEA | 1.10 | 53 | SOC1 | 4.8 | V-1 | C | C |
| Example 4 | P-4 | PGMEA | 1.07 | 53 | SOC1 | 3.0 | V-1 | B | C |
| Example 5 | P-5 | PGMEA | 1.11 | 53 | SOC1 | 3.9 | V-1 | A | A |
| Example 6 | P-6 | PGMEA | 1.08 | 54 | SOC1 | 4.5 | V-1 | A | B |
| Example 7 | P-7 | PGMEA | 1.55 | 40 | SOC1 | 3.8 | V-1 | A | C |
| | | Cyclohexanone | | | | | | | |
| Example 8 | P-8 | PGMEA | 1.26 | 62 | SOC1 | 5.2 | V-1 | B | B |
| | | PGME | | | | | | | |
| Example 9 | P-9 | PGMEA | 1.10 | 50 | SOC1 | 0.9 | V-1 | A | A |
| Example 10 | P-10 | PGMEA | 1.08 | 49 | SOC1 | 0.8 | V-1 | A | A |
| Example 11 | P-11 | PGMEA | 1.08 | 50 | SOC1 | 0.8 | V-1 | A | A |
| Example 12 | P-1 | PGME | 1.08 | 52 | SOC1 | 2.0 | V-1 | A | A |
| Example 13 | P-1 | PGMEA | 1.08 | 52 | SOC2 | 2.2 | V-1 | A | A |
| Example 14 | P-1 | PGMEA | 1.08 | 52 | SOC3 | 2.5 | V-1 | A | A |
| Example 15 | P-1 | PGMEA | 1.08 | 52 | SOC1 | 2.0 | V-2 | A | A |
| Example 16 | P-12 | PGMEA | 1.08 | 48 | SOC1 | 1.8 | V-1 | A | A |
| Example 17 | P-13 | PGMEA | 1.10 | 50 | SOC1 | 1.9 | V-1 | A | A |
| Example 18 | P-14 | PGMEA | 1.12 | 49 | SOC1 | 1.1 | V-1 | A | B |
| Example 19 | P-15 | PGMEA | 1.13 | 54 | SOC1 | 0.8 | V-1 | A | A |
| Example 20 | P-16 | PGMEA | 1.09 | 52 | SOC1 | 0.9 | V-1 | A | A |
| Example 21 | P-17 | PGMEA | 1.13 | 52 | SOC1 | 1.8 | V-1 | A | A |
| Example 22 | P-18 | PGMEA | 1.14 | 50 | SOC1 | 1.1 | V-2 | A | A |
| Example 23 | P-19 | PGMEA | 1.10 | 53 | SOC1 | 1.3 | V-1 | A | A |
| Example 24 | P-20 | PGMEA | 1.10 | 53 | SOC1 | 1.3 | V-1 | A | A |
| Example 25 | P-21 | PGMEA | 1.15 | 48 | SOC1 | 0.6 | V-1 | A | A |
| Example 26 | P-22 | PGMEA | 1.10 | 50 | SOC1 | 0.9 | V-1 | A | A |
| Example 27 | P-23 | PGMEA | 1.19 | 53 | SOC1 | 0.8 | V-1 | A | A |
| Example 28 | P-24 | PGMEA | 1.23 | 60 | SOC1 | 8.0 | V-1 | C | B |
| | | γBL | | | | | | | |
| Example 29 | P-25 | PGMEA | 1.19 | 53 | SOC1 | 2.0 | V-1 | A | A |
| Example 30 | P-26 | PGMEA | 1.10 | 54 | SOC1 | 5.0 | V-1 | B | A |
| Example 31 | P-1 | PGMEA | 1.08 | 52 | SOC1 | 2.0 | V-3 | A | A |
| Example 32 | P-22 | PGMEA | 1.10 | 50 | SOC1 | 0.9 | V-3 | A | A |
| Example 33 | P-26 | PGMEA | 1.10 | 54 | SOC1 | 5.0 | V-3 | A | A |

TABLE 2

| | Composition for forming | | Adhesive film | | Laminate | | | Evaluation | |
|---|---|---|---|---|---|---|---|---|---|
| | adhesive film | | Film density | γₐ | | γ_{ab} | Composition for | Peeling | Bubble |
| | Resin | Solvent | [g/cm³] | [mJ/m²] | Substrate | [mJ/m²] | forming pattern | defects | defects |
| Comparative | RP-1 | PGMEA | 1.24 | 57 | SOC1 | 12.0 | V-1 | E | E |
| Example 1 | | | | | | | | | |
| Comparative | RP-2 | PGMEA | 1.12 | 46 | SOC1 | 10.0 | V-1 | E | E |
| Example 2 | | | | | | | | | |
| Comparative | RP-3 | PGMEA | 1.19 | 50 | SOC1 | 9.0 | V-1 | E | D |
| Example 3 | | | | | | | | | |
| Comparative | RP-4 | PGMEA | 1.15 | 47 | SOC1 | 2.5 | V-1 | E | E |
| Example 4 | | | | | | | | | |
| Comparative | RP-5 | PGMEA | 1.01 | 48 | SOC1 | 9.0 | V-1 | E | C |
| Example 5 | | | | | | | | | |
| Comparative | RP-6 | PGMEA | 1.15 | 62 | SOC1 | 15.0 | V-1 | E | E |
| Example 6 | | | | | | | | | |
| Comparative | RP-1 | PGMEA | 1.24 | 57 | Si | 3.0 | V-1 | B | E |
| Example 7 | | | | | | | | | |
| Comparative | RP-3 | PGMEA | 1.19 | 50 | Si | 1.5 | V-1 | A | E |
| Example 8 | | | | | | | | | |
| Comparative | RP-1 | PGMEA | 1.24 | 57 | SOC2 | 10.0 | V-1 | E | E |
| Example 9 | | | | | | | | | |
| Comparative | RP-1 | PGMEA | 1.24 | 57 | SOC3 | 10.0 | V-1 | C | E |
| Example 10 | | | | | | | | | |
| Comparative | RP-7 | PGMEA | 1.11 | 57 | SOC2 | 9.5 | V-2 | D | A |
| Example 11 | | | | | | | | | |

Specifications of respective materials are as follows.

<<Resin>>

In the following tables, a numerical value in parentheses in the main chain represents a molar ratio of each repeating unit, and a numerical value in parentheses in the side chain represents a repetition number in each repeating unit. In a case where an aromatic ring in the side chain has a plurality of substituents, the maximum value among the formula weights of each substituent is shown in the column of “Formula weight of substituent of aromatic ring”. Since the aromatic ring is not in the side chain in RP-5, in the columns of “Formula weight of substituent of aromatic ring” and “Proportion of repeating unit including aromatic ring” of RP-5, reference values are shown in that they have an aromatic ring.

TABLE 3

| | P-1 | | P-2 | |
|---|---|---|---|---|
| | Repeating unit A | Repeating unit B | Repeating unit A | Repeating unit B |
| Compound | 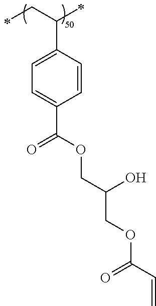 | 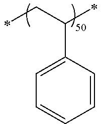 | 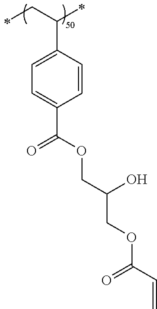 | 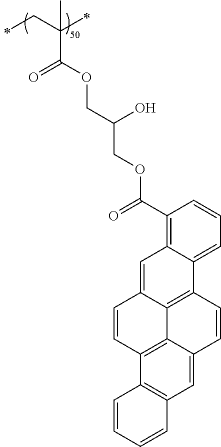 |
| Formula weight of | 276 | 104 | 276 | 489 |
| repeating unit | | | | |
| Formula weight of | 173 | Unsubstituted | 173 | Unsubstituted |
| substituent of | | | | |
| aromatic ring | | | | |
| Proportion of | 100% by mass | | 100% by mass | |
| repeating | | | | |
| unit including | | | | |
| aromatic ring | | | | |
| Proportion of | 72.6% by mass | | 35.2% by mass | |
| repeating | | | | |
| unit including | | | | |
| polymerizable group | | | | |
| Film density | 1.08 g/cm³ | | 0.97 g/cm³ | |
| Surface free energy | 52 mJ/m² | | 46 mJ/m² | |
| of film | | | | |
| | P-3 | | P-4 | |
| | Repeating unit A | Repeating unit B | Repeating unit A | Repeating unit B |
| Compound | 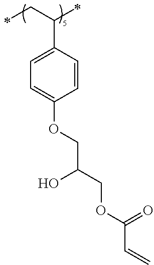 | 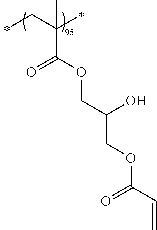 | 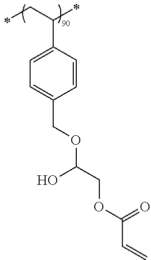 | 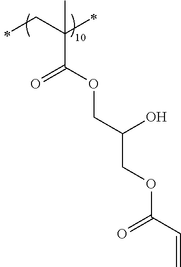 |
| Formula weight of | 248 | 214 | 248 | 214 |
| repeating unit | | | | |
| Formula weight of | 145 | — | 145 | — |
| substituent of | | | | |
| aromatic ring | | | | |
| Proportion of | 5.7% by mass | | 91.3% by mass | |
| repeating unit | | | | |
| including aromatic | | | | |
| ring | | | | |
| Proportion of | 100% by mass | | 100% by mass | |
| repeating | | | | |
| unit including | | | | |
| polymerizable group | | | | |
| Film density | 1.10 g/cm³ | | 1.07 g/cm³ | |
| Surface free energy | 53 mJ/m² | | 53 mJ/m² | |
| of film | | | | |

TABLE 4

| | P-5 | | P-6 | |
|---|---|---|---|---|
| | Repeating unit A | Repeating unit B | Repeating unit A | Repeating unit B |
| Compound | 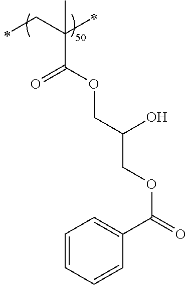 | 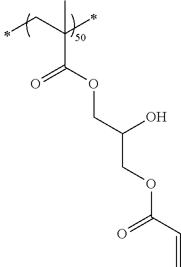 | 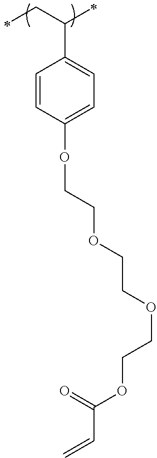 | None |
| Formula weight of | 264 | 214 | 306 | — |
| repeating unit | | | | |
| Formula weight of | Unsubstituted | — | 203 | — |
| substituent of | | | | |
| aromatic ring | | | | |
| Proportion of | 55.2% by mass | | 100% by mass | |
| repeating | | | | |
| unit including | | | | |
| aromatic ring | | | | |
| Proportion of | 44.8% by mass | | 100% by mass | |
| repeating | | | | |
| unit including | | | | |
| polymerizable group | | | | |
| Film density | 1.11 g/cm³ | | 1.08 g/cm³ | |
| Surface free energy | 53 mJ/m² | | 54 mJ/m² | |
| of film | | | | |
| | P-7 | | P-8 | |
| | Repeating unit A | Rxepeating unit B | Repeating unit A | Repeating unit B |
| Compound | 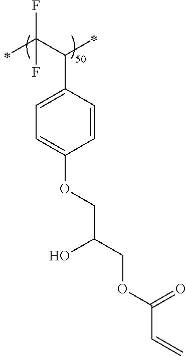 | 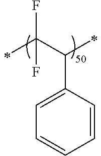 | 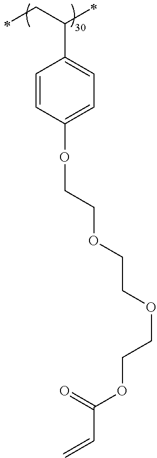 | 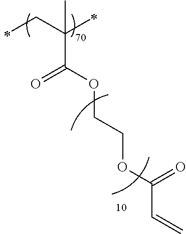 |
| Fomula weight of | 284 | 140 | 306 | 581 |
| repeating unit | | | | |
| Formula weight of | 145 | Unbubstituted | 203 | — |
| substituent of | | | | |
| aromatic ring | | | | |
| Proportion of | 100% by mass | | 18.4% by mass | |
| repeating unit | | | | |
| including aromatic | | | | |
| ring | | | | |
| Proportion of | 67.0% by mass | | 100% by mass | |
| repeating | | | | |
| unit including | | | | |
| polymerizable group | | | | |
| Film density | 1.55 g/cm³ | | 1.26 g/cm³ | |
| Surface free energy | 40 mJ/m² | | 62 mJ/m² | |
| of film | | | | |

TABLE 5

| | P-9 | | P-10 | |
|---|---|---|---|---|
| | Repeating unit A | Repeating unit B | Repeating unit A | Repeating unit B |
| Compound | 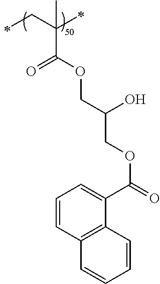 | 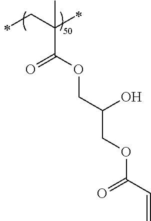 | 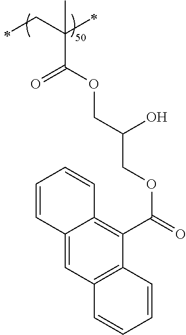 | 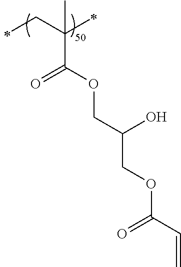 |
| Formula weight of | 314 | 214 | 364 | 214 |
| repeating unit | | | | |
| Formula weight of | Unsubstituted | — | Unsubstituted | — |
| substituent of | | | | |
| aromatic ring | | | | |
| Proportion of | 59.5% by mass | | 63.0% by mass | |
| repeating | | | | |
| unit including aromatic | | | | |
| ring | | | | |
| Proportion of repeating | 40.5% by mass | | 37.0% by mass | |
| unit including | | | | |
| polymerizable group | | | | |
| Film density | 1.10 g/cm³ | | 1.08 g/cm³ | |
| Surface free energy of | 50 mJ/m² | | 49 mJ/m² | |
| film | | | | |
| | P-11 | | P-12 | |
| | Repeating unit A | Repeating unit B | Repeating unit A | Repeating unit B |
| Compound | 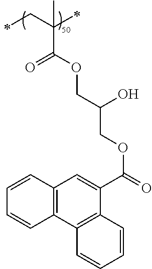 | 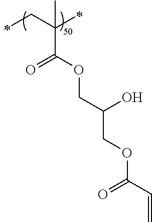 | 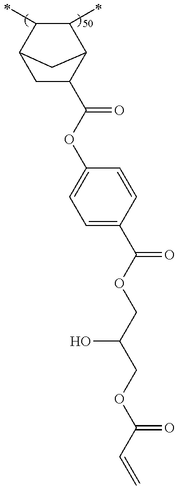 | 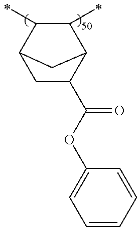 |
| Formula weight of | 364 | 214 | 386 | 214 |
| repeating unit | | | | |
| Formula weight of | Unsubstituted | — | 173 | Unsubstituted |
| substituent of aromatic | | | | |
| ring | | | | |
| Proportion of repeating | 63.0% by mass | | 100.0% by mass | |
| unit including aromatic | | | | |
| ring | | | | |
| Proportion of repeating | 37.0% by mass | | 64.3% by mass | |
| unit including | | | | |
| polymerizable group | | | | |

| | | |
|---|---|---|
| Film density | 1.08 g/cm³ | 1.08 g/cm³ |
| Surface free energy of | 50 mJ/m² | 48 mJ/m² |
| film | | |

TABLE 6

| | P-13 | | P-14 | |
|---|---|---|---|---|
| | Repeating unit A | Repeating unit B | Repeating unit A | Repeating unit B |
| Compound | 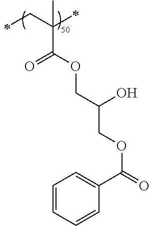 | 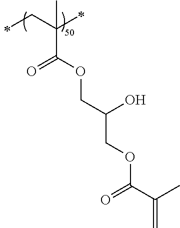 | 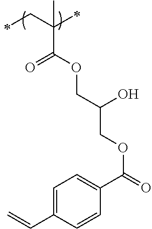 | None |
| Formula weight of | 264 | 228 | 290 | — |
| repeating unit | | | | |
| Formula weight of | Unsubstitued | — | 27 | — |
| substituent of | | | | |
| aromatic ring | | | | |
| Proportion of | 53.7% by mass | | 100.0% by mass | |
| repeating unit | | | | |
| including aromatic | | | | |
| ring | | | | |
| Proportion of | 46.3% by mass | | 100.0% by ass | |
| repeating | | | | |
| unit including | | | | |
| polymerizable group | | | | |
| Film density | 1.10 g/cm³ | | 1.12 g/cm³ | |
| Surface free energy | 50 mJ/m² | | 49 mJ/m² | |
| of film | | | | |
| | P-15 | | P-16 | |
| | Repeating unit A | Repeating unit B | Repeating unit A | Repeating unit B |
| Compound | 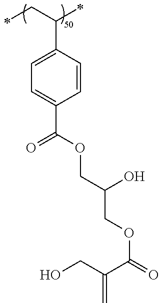 | 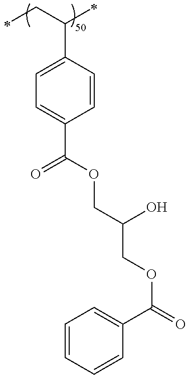 | 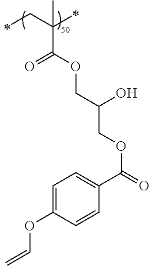 | 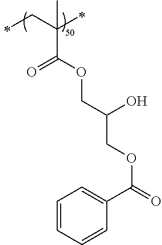 |
| Formula weight of | 306 | 326 | 306 | 264 |
| repeating unit | | | | |
| Formula weight of | 203 | Unsubstituted | 43 | Unsubstituted |
| substituent of | | | | |
| aromatic ring | | | | |
| Proportion of | 100.0% by mass | | 100.0% by mass | |
| repeating unit | | | | |
| including aromatic | | | | |
| ring | | | | |
| Proportion of | 48.4% by mass | | 53.7% by mass | |
| repeating | | | | |
| unit including | | | | |
| polymerizable group | | | | |
| Film density | 1.13 g/cm³ | | 1.09 g/cm³ | |
| Surface free energy | 54 mJ/m² | | 52 mJ/m² | |
| of film | | | | |

TABLE 7

| | P-17 | | P-18 | |
|---|---|---|---|---|
| | Repeating unit A | Repeating unit B | Repeating unit A | Repeating unit B |
| Compound | 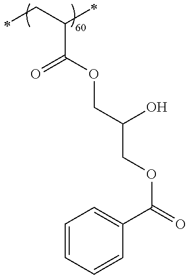 | 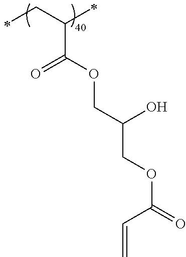 | 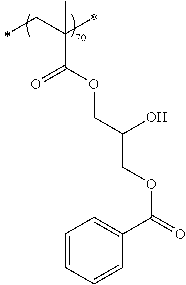 | 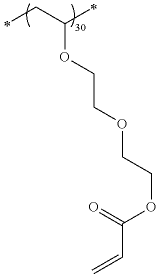 |
| Formula weight of | 250 | 200 | 264 | 186 |
| repeating unit | | | | |
| Formula weight of | Unsubstituted | — | Unsubstituted | — |
| substituent of | | | | |
| aromatic ring | | | | |
| Proportion of | 65.2% by mass | | 76.8% by mass | |
| repeating unit | | | | |
| including aromatic | | | | |
| ring | | | | |
| Proportion of | 34.8% by mass | | 23.2% by mass | |
| repeating | | | | |
| unit including | | | | |
| polymerizable group | | | | |
| Film density | 1.13 g/cm³ | | 1.14 g/cm³ | |
| Surface free energy | 52 mJ/m² | | 50 mJ/m² | |
| of film | | | | |
| | P-19 | | P-20 | |
| | Repeating unit A | Repeating unit B | Repeating unit A | Repeating unit B |
| Compound | 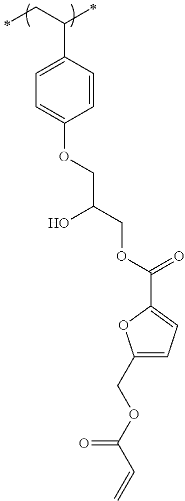 | None | 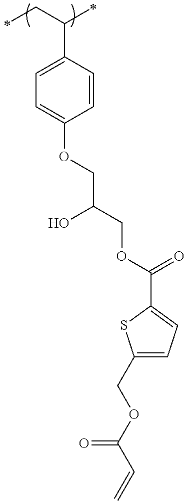 | None |
| Formula weight of | 372 | — | 388 | — |
| repeating unit | | | | |
| Formula weight of | 85 | — | 85 | — |
| substituent of | | | | |
| aromatic ring | | | | |
| Proportion of | 100.0% by mass | | 100.0% by mass | |
| repeating unit | | | | |
| including aromatic | | | | |
| ring | | | | |
| Proportion of | 100.0% by mass | | 100.0% by mass | |
| repeating | | | | |
| unit including | | | | |
| polymerizable group | | | | |
| Film density | 1.10 g/cm³ | | 1.10 g/cm³ | |
| Surface free energy | 53 mJ/m² | | 53 mJ/m² | |
| of film | | | | |

TABLE 8

| | P-21 | | P-22 | |
|---|---|---|---|---|
| | Repeating unit A | Repeating unit B | Repeating unit A | Repeating unit B |
| Compound | 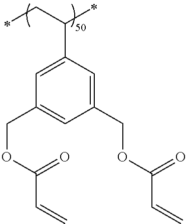 | 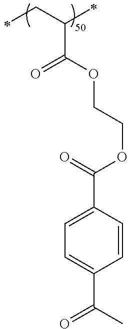 | 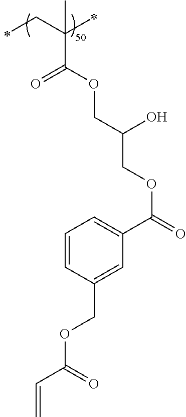 | 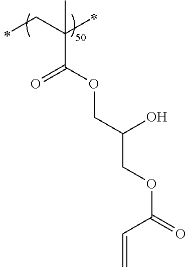 |
| Formula weight of | 272 | 262 | 348 | 214 |
| repeating unit | | | | |
| Formula weight of | 85 | 43 | 85 | — |
| substituent of aromatic | | | | |
| ring | | | | |
| Proportion of repeating | 100.0% by mass | | 61.9% by mass | |
| unit including aromatic | | | | |
| ring | | | | |
| Proportion of repeating | 50.9% by mass | | 100.0% by mass | |
| unit including | | | | |
| polymerizable group | | | | |
| Film density | 1.15 g/cm³ | | 1.10 g/cm³ | |
| Surface free energy of | 48 mJ/m² | | 50 mJ/m² | |
| film | | | | |
| | P-23 | | P-24 | |
| | Repeating unit A | Repeating unit B | Repeating unit A | Repeating unit B |
| Compound | 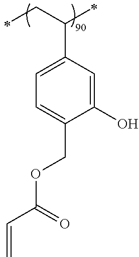 | 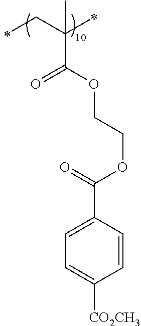 | 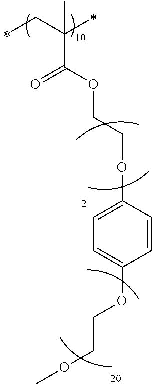 | 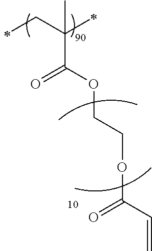 |
| Formula weight of | 204 | 292 | 1161 | 581 |
| repeating unit | | | | |
| Formula weight of | 85 | 59 | 912 | — |
| substituent of aromatic | | | | |
| ring | | | | |
| Proportion of repeating | 100.0% by mass | | 18.2% by mass | |
| unit including aromatic | | | | |
| ring | | | | |
| Proportion of repeating | 86.3% by mass | | 81.8% by mass | |
| unit including | | | | |
| polymerizable group | | | | |
| Film density | 1.19 g/cm³ | | 1.23 g/cm³ | |
| Surface free energy of | 53 mJ/m² | | 60 mJ/m² | |
| film | | | | |

TABLE 9

| | P-25 | |
|---|---|---|
| | Repeating unit A | Repeating unit B |
| Compound | 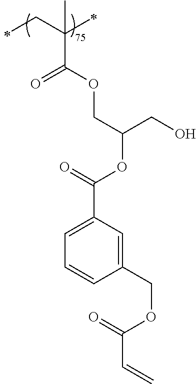 | 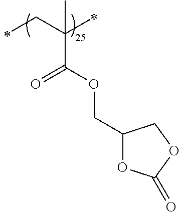 |
| Formula weight of repeating unit | 348 | 186 |
| Formula weight of substituent of | 85 | — |
| aromatic ring | | |
| Proportion of repeating unit | 84.8% by mass | |
| including aromatic ring | | |
| Proportion of repeating unit | 84.8% by mass | |
| including polymerizable group | | |

| Film density | 1.19 g/cm³ | | |
|---|---|---|---|
| Surface free energy of film | 53 mJ/m² | | |
| | P-26 | | |
| | Repeating unit A | Repeating unit B | Repeating unit C |
| Compound | 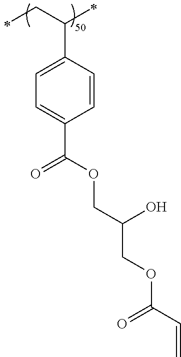 | 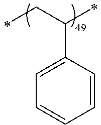 | 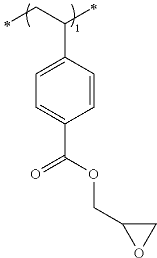 |
| Formula weight of repeating unit | 276 | 104 | 204 |
| Formula weight of substituent of | 173 | Unsubstituted | 101 |
| aromatic ring | | | |
| Proportion of repeating unit | 100.0% by mass | | |
| including aromatic ring | | | |
| Proportion of repeating unit | 73.3% by mass | | |
| including polymerizable group | | | |

| | |
|---|---|
| Film density | 1.10 g/cm³ |
| Surface free energy of film | 54 mJ/m² |

TABLE 10

| | RP-1 | | RP-2 | |
|---|---|---|---|---|
| | Repeating unit A | Repeating unit B | Repeating unit A | Repeating unit B |
| Compound | 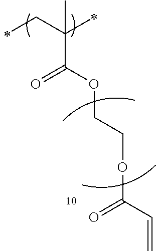 | None | 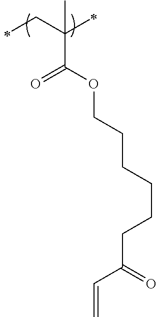 | None |
| Formula weight of | 581 | — | 224 | — |
| repeating unit | | | | |
| Formula weight of | — | — | — | — |
| substituent of aromatic | | | | |
| ring | | | | |
| Proportion of repeating | 0% by mass | | 0% by mass | |
| unit including aromatic | | | | |
| ring | | | | |
| Proportion of repeating | 100% by mass | | 100% by mass | |
| unit including | | | | |
| polymerizable group | | | | |
| Film density | 1.24 g/cm³ | | 1.12 g/cm³ | |
| Surface free energy of | 57 mJ/m² | | 46 mJ/m² | |
| film | | | | |
| | RP-3 | | RP-4 | |
| | Repeating unit A | Repeating unit B | Repeating unit A | Repeating unit B |
| Compound | 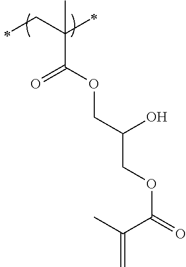 | None | 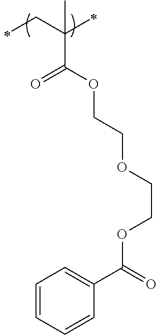 | None |
| Formula weight of | 228 | — | 278 | — |
| repeating unit | | | | |
| Formula weight of | — | — | Unsubstituted | — |
| substituent of aromatic | | | | |
| ring | | | | |
| Proportion of repeating | 0% by mass | | 100% by mass | |
| unit including aromatic | | | | |
| ring | | | | |
| Proportion of repeating | 100% by mass | | 0% by mass | |
| unit including | | | | |
| polymerizable group | | | | |
| Film density | 1.19 g/cm³ | | 1.15 g/cm³ | |
| Surface free energy of | 50 mJ/m² | | 47 mJ/m² | |
| film | | | | |

TABLE 11

| | RP-5 | | RP-6 | |
|---|---|---|---|---|
| | Repeating unit A | Repeating unit B | Repeating unit A | Repeating unit B |
| Compound | 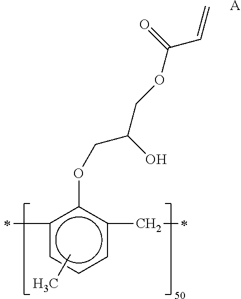 | | 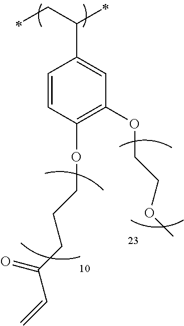 | None |
| | 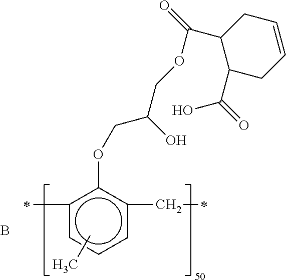 | | | |
| Formula weight of | 264 | 362 | 1658 | — |
| repeating unit | | | | |
| Formula weight of | (145) | (243) | 1044 | — |
| substituent of aromatic | | | | |
| ring | | | | |
| Proportion of repeating | (100% by mass) | | 100% by mass | |
| unit including aromatic | | | | |
| ring | | | | |
| Proportion of repeating | 100% by mass | | 100% by mass | |
| unit including | | | | |
| polymerizable group | | | | |
| Film density | 1.01 g/cm³ | | 1.15 g/cm³ | |
| Surface free energy of | 48 mJ/m² | | 62 mJ/m² | |
| film | | | | |

| | RP-7 | | |
|---|---|---|---|
| | Repeating unit A | Repeating unit B | Repeating unit C |
| Compound | 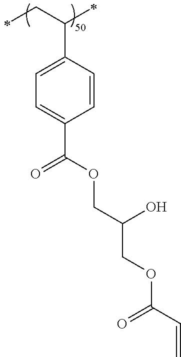 | 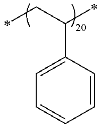 | 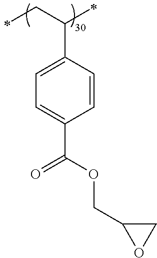 |
| Formula weight of | 276 | 104 | 204 |
| repeating unit | | | |
| Formula weight of | 173 | Unsubstituted | 101 |
| substituent of aromatic | | | |
| ring | | | |
| Proportion of repeating | 100% by mass | | |
| unit including aromatic | | | |
| ring | | | |
| Proportion of repeating | 90.5% by mass | | |
| unit including | | | |
| polymerizable group | | | |
| Film density | 1.11 g/cm³ | | |
| Surface free energy of | 57 mJ/m² | | |
| film | | | |

<<Solvent>>
PGMEA: propylene glycol monomethyl ether acetate
PGME: propylene glycol monomethyl ether
γBL: γ-butyrolactone

<<Substrate>>
SOC1: carbon-containing support in which an SOC film was formed on a silicon wafer; a carbon content on a surface was 80% by mass or more.
SOC2: carbon-containing support in which an SOC film was formed on a silicon wafer; a carbon content on a surface was 60% by mass or more and less than 80% by mass.
SOC3: carbon-containing support in which an SOC film was formed on a silicon wafer; a carbon content on a surface was 40% by mass or more and less than 60% by mass.

<Formation of Laminate>

Each composition for forming an adhesive film of Examples and Comparative Examples was applied onto substrates listed in each table by a spin coating method, and heated at 250° C. for 1 minute to form an adhesive film. A thickness of the adhesive film was 5 nm.

<Measurement of Film Density>

For the adhesive film formed by the above-described method, using an X-ray reflectance measuring device (ATX-G, manufactured by Rigaku Corporation), a film density of the adhesive film formed on the silicon wafer as a sample was determined by X-ray reflectance measurement. A Cu target was used as an X-ray source, and X-rays were generated at 50 kV and 300 mA. Specific measurement conditions are as follows.

Measurement Conditions
S1 slit: width 1.0 mm, height 10 mm
Optical element on incident side: none
S2 slit: width 1.0 mm, height 10 mm
Receiving slit: width 1.0 mm, height 10 mm
Optical element on light-receiving side: none
Gurd slit: width 0.5 mm, height 10 mm
Scan axis: 2θ/ω, scan range 0 to 20 degrees, sampling width 0.01 degrees
Scan speed: 0.1 degrees/min (in a case of scanning 2θ/ω=0 to 2 degrees), 0.05 degrees/min (in a case of scanning 2θ/ω=0.5 to 20 degrees)

In the measurement of 2θ/ω=0 to 2 degrees, from the viewpoint of detector protection, a damping member with eight A1 foils stacked separately was installed.

From the measurement data in a range of 2θ/ω=0.5 to 2 degrees in the case of scanning 2θ/ω=0 to 2 degrees and the measurement data in a range of 0.5 to 2 degrees in the case of scanning 2θ/ω=0.5 to 20 degrees, influence of X-ray attenuation due to the A1 foil was corrected. In addition, after connecting both data by a sigmoid function, influence of a signal value due to X-ray scattering (Thomson scattering and Compton scattering) by the silicon wafer was calculated from the measurement data in a range of 2θ/ω=15 to 20 degrees to correct the measurement data. Based on these corrected measurement data, an incidence angle dependence profile of X-ray reflectivity was created. On the other hand, a profile was also created by simulating the film thickness, density, interface roughness, and the like as parameters based on a film structure model. Structural parameters (film density, film thickness, and the like) of a thin film were calculated by optimizing the errors of these profiles to be small. For details on the analysis of film properties by X-ray reflectance measurement, for example, Rigaku Journal, Vol. 40, No. 2 (2009), pp. 1 to 9 and Journal of Surface Analysis, Vol. 9, No. 2 (2002), pp. 203 to 209 can be referred to, the contents of which are incorporated in the present specification.

<Measurement of Surface Free Energy>

Regarding the adhesive film and substrate formed by the above-described method, based on Kaelbel-Uy theory, a dispersion component and a polar component of surface free energy were calculated from measured values of a contact angle of a solvent, and by applying Expression (1) and Expression (2), a surface free energy γₐ of the adhesive film and a surface free energy γ_{ab} at an interface between the substrate and the adhesive film were calculated, respectively. For the measurement of the contact angle, a fully automatic contact angle meter DMo-901 (manufactured by Kyowa Interface Science Co., Ltd.) was used. As the solvent having a known surface strength, water and diiodomethane were preferentially used, and formamide, oleic acid, and n-hexadecane were used as necessary.

<Preparation of Composition for Forming Pattern>

Preparation was performed by formulating compounds shown in Table 12 below in formulation proportions (parts by mass) shown in the following table, and further adding 4-hydroxy-2,2,6,6-tetramethylpiperidine-1-oxyl free radical (manufactured by Tokyo Chemical Industry Co., Ltd.) as a polymerization inhibitor so that the amount thereof was 200 ppm by mass (0.02% by mass) with respect to the total amount of polymerizable compounds (Nos. 1 to 3 in the table). The mixture was filtered with a nylon filter having a pore diameter of 0.02 μm and an ultra-high-molecular-weight polyethylene (UPE) filter having a pore diameter of 0.001 μm to prepare compositions V-1 and V-2 for forming a pattern. In the table, k+m+n is 10.

TABLE 12

| | Composition V-1 for forming pattern | | Composition V-2 for forming pattern | |
|---|---|---|---|---|
| | | Formulation | | Formulation |
| | | ratio (part | | ratio (part |
| No. | Compound | by mass) | Compound | by mass) |
| 1 | 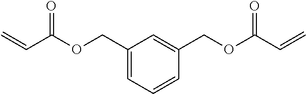 [SMILES: C=CC(=O)OCc1cccc(COC(=O)C=C)c1] | 65 | 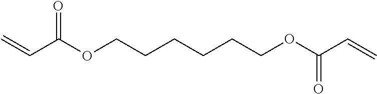 [SMILES: C=CC(=O)OCCCCCCOC(=O)C=C] | 50 |
| 2 | 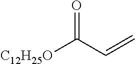 | 20 | 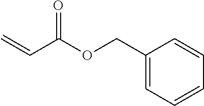 | 40 |
| 3 | 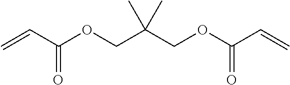 | 15 | 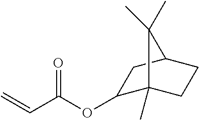 | 10 |
| 4 | 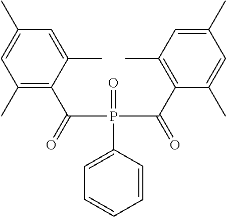 [SMILES: Cc1cc(C)c(C(=O)P(=O)(C(=O)c2c(C)cc(C)cc2C)c2ccccc2)c(C)c1] | 2 | 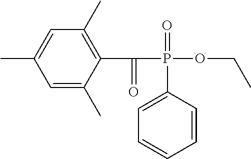 [SMILES: CCOP(=O)(C(=O)c1c(C)cc(C)cc1C)c1ccccc1] | 1 |
| 5 | 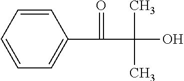 | 2 | 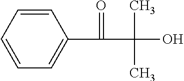 | 2 |
| 6 | 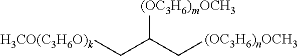 | 3 | Fluorine-based surfactant Capstone FS-3100 (manufactured by DuPont) | 2 |

In addition, each compound described below were mixed at the following composition, and 4-hydroxy-2,2,6,6-tetramethylpiperidine-1-oxyl free radical (manufactured by Tokyo Chemical Industry Co., Ltd.) as a polymerization inhibitor was further added thereto so that the amount thereof was 200 ppm by mass (0.02% by mass) with respect to a silicone polymer 1 for the preparation. The mixture was filtered with a nylon filter having a pore diameter of 0.02 μm and an ultra-high-molecular-weight polyethylene (UPE) filter having a pore diameter of 0.001 μm to prepare composition V-3 for forming a pattern.
Composition of composition V-3 for forming a pattern

Following silicone polymer 1: 8.3 parts by mass

Compound same as No. 4 of composition V2: 0.7 parts by mass

Compound same as No. 5 of composition V2: 0.3 parts by mass

Compound same as No. 6 of composition V2: 0.7 parts by mass

PGMEA: 90.0 parts by mass

Method for Synthesizing Silicone Polymer 1

A silicone resin X-40-9225 (trade name, manufactured by Shin-Etsu Chemical Co., Ltd.) (10 parts), 2-hydroxyethyl acrylate (58.1 parts), and paratoluene sulfonic acid monohydrate (0.034 parts) were mixed with each other, and then the mixture was heated at 120° C. and stirred for 3 hours while distilling off methanol produced by a condensation reaction to obtain 48 parts of the silicone polymer 1.

<Evaluation>

For each composition for forming an adhesive film of Examples and Comparative Examples obtained above, a degree of suppression of peeling defects and bubble defects was evaluated by the following procedure.

In a case of using V-1 or V-2 as a composition for forming a pattern, the above-described composition (V-1 or V-2) for forming a pattern, of which the temperature was adjusted to 25° C., according to each of Examples and Comparative Examples was jetted in a liquid droplet amount of 6 pL per nozzle to a surface of the adhesive film obtained above using an ink jet printer DMP-2831 manufactured by FUJIFILM Dimatix Inc., and liquid droplets were applied onto the adhesive film in a square array with intervals of about 100 μm, thereby forming a composition layer for forming a pattern.

In a case of using V-3 as a composition for forming a pattern, the composition (V-3) for forming a pattern was applied onto a closely adhesive layer by a spin coating method, and then heated at 80° C. for 1 minute to form a composition layer for forming a pattern having a thickness of 40 nm.

Subsequently, a mold was pressed against the composition layer for forming a pattern under a He atmosphere (substitution rate of 90% by volume or more), and the pattern of the mold was filled with the composition for forming a pattern. The used mold is a quartz mold with a line/space pattern having a line width of 28 nm, a depth of 60 nm, and a pitch of 60 nm. When 10 seconds passed after the imprinting, exposure was performed from a mold side using a high-pressure mercury lamp under a condition of 150 mJ/cm², and then the mold was peeled off to transfer a pattern to the composition layer for forming a pattern.

The transferred pattern was observed by optical microscope observation (macro-observation) and scanning electron microscope observation (micro-observation), and based on the following standard, the degree of suppression of peeling defects and bubble defects was evaluated. The evaluations of A to C are levels suitable for practical use.

<<Evaluation of Peeling Defects>>
A: Pattern peeling was not observed in any of the observations.
B: In the macro-observation, pattern peeling was not observed, but in the micro-observation, pattern peeling was observed.
C: In the macro-observation, peeling was observed in some regions (release end part).
D: In the macro-observation, peeling was observed in multiple regions (release end part).
E: None of A to D were applicable.

<<Evaluation of Bubble Defects>>
A: Unfilled region (bubble defect) of the composition for forming a pattern was not observed in any of the observations.
B: The density of bubble defects was less than 1.0 pieces/cm².
C: The density of bubble defects was 1.0 pieces/cm² or more and 5.0 pieces/cm².
D: The density of bubble defects was 5.0 pieces/cm² or more and 8.0 pieces/cm².
E: The density of bubble defects was 8.0 pieces/cm² or more.

<Evaluation Result>

The evaluation results of the respective Examples and Comparative Examples are shown in Tables 1 and 2. From the results, by using the composition for forming an adhesive film according to the embodiment of the present invention, it was found that, in a case where the composition for forming a pattern is applied to a carbonaceous material on a surface of a substrate by an imprinting method, the pattern peeling during mold peeling was suppressed, and sufficient adhesiveness between the substrate and the composition for forming a pattern could be ensured. Furthermore, according to the present invention, it was also found that gas permeability and wettability of the adhesive film in a case of pressing the mold were improved, and the bubble defects were suppressed.

In addition, the adhesive film was formed on the carbon-containing support using the composition for forming an adhesive film according to each Example, and a predetermined pattern corresponding to a semiconductor circuit was formed on the carbon-containing support with the adhesive film using the composition for forming a pattern according to each Example. Each carbon-containing support was dry-etched by using this pattern as an etching mask, and each semiconductor element was produced using this support. There was no problem with the performance of any of the semiconductor elements.

### EXPLANATION OF REFERENCES

1: substrate
2: adhesive film
3: composition for forming pattern
4: mold

What is claimed is:

1. A composition for forming an adhesive film for imprinting, comprising:
a resin having a specific aromatic ring and a polymerizable functional group in a side chain,
wherein the specific aromatic ring is an unsubstituted aromatic ring, or an aromatic ring having one or more substituents, in which a formula weight of each of the one or more substituents is 1000 or less, and
a proportion of a polymerizable functional group including a heterocyclic ring in the polymerizable functional group is less than 3 mol %.

2. The composition for forming an adhesive film according to claim 1,
wherein the formula weight of each of the one or more substituents is 250 or less.

3. The composition for forming an adhesive film according to claim 1,
wherein the specific aromatic ring is a single ring or a fused ring having 2 to 5 rings.

4. The composition for forming an adhesive film according to claim 1,
wherein the specific aromatic ring is an unsubstituted aromatic ring.

5. The composition for forming an adhesive film according to claim 1,
wherein the specific aromatic ring is one of a benzene ring, a naphthalene ring, an anthracene ring, or a phenanthrene ring.

6. The composition for forming an adhesive film according to claim 1,
wherein the specific aromatic ring is linked to a main chain of the resin through a single bond or a linking group having a link length of 1 to 10 atoms.

7. The composition for forming an adhesive film according to claim 1,
wherein the resin includes at least one of a resin including a repeating unit represented by Formula (AD-1) or a resin including a repeating unit represented by Formula (AD-2) and a repeating unit represented by Formula (AD-3), 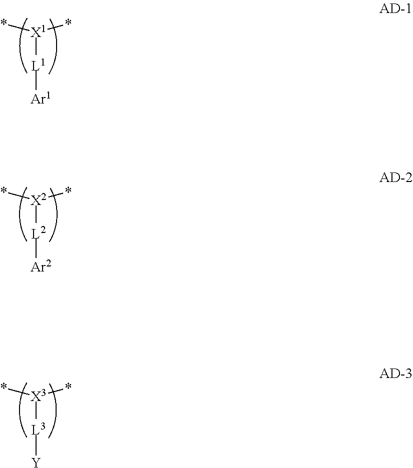
in Formula (AD-1),
X¹ represents a trivalent linking group,
L¹ represents a single bond or a divalent linking group, and
Ar¹ represents a group which includes the specific aromatic ring and the polymerizable functional group, and
* represents a bonding site with a main chain,
in Formula (AD-2) and Formula (AD-3),
X² and X³ each independently represent a trivalent linking group,
L² and L³ each independently represent a single bond or a divalent linking group,
Ar² represents a group which includes the specific aromatic ring and does not include the polymerizable functional group,
Y represents the polymerizable functional group, and
* represents a bonding site with a main chain.

8. The composition for forming an adhesive film according to claim 7,
wherein the linking groups X¹, X², and X³ are each independently a group represented by any one of Formula (AD-X1), Formula (AD-X2), or Formula (AD-X3), 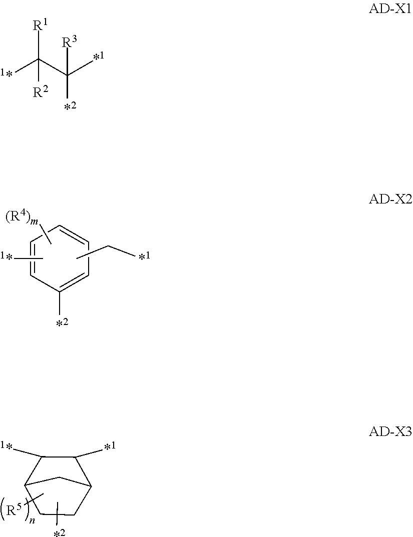
in Formulae (AD-X1) to (AD-X3),
R¹ to R³ each independently represent a hydrogen atom or a monovalent substituent,
R⁴ and R⁵ each independently represent a monovalent substituent,
m and n each independently represent an integer of 0 to 3,
*1 represents a bonding part with a main chain of the resin, and
*2 represents a bonding part with any of the linking groups L¹, L², or L³.

9. The composition for forming an adhesive film according to claim 8,
wherein the linking groups X¹, X², and X³ are groups represented by Formula (AD-X1).

10. The composition for forming an adhesive film according to claim 7,
wherein the linking groups L¹, L², and L³ include an aromatic ring.

11. The composition for forming an adhesive film according to claim 7,
wherein a mass ratio C2/C3 of a content C2 of the repeating unit represented by Formula (AD-2) to a content C3 of the repeating unit represented by Formula (AD-3) is 0.33 to 3.0.

12. The composition for forming an adhesive film according to claim 7,
wherein a proportion of a repeating unit including the specific aromatic ring in the resin is 50% to 100% by mass with respect to all repeating units in the resin.

13. The composition for forming an adhesive film according to claim 7,
wherein a proportion of a repeating unit including the polymerizable functional group in the resin is 50% to 100% by mass with respect to all repeating units in the resin.

14. An adhesive film formed from the composition for forming an adhesive film according to claim 1.

15. The adhesive film according to claim 14,
wherein a film density is 0.90 to 1.60 g/cm³.

16. The adhesive film according to claim 14,
wherein a surface free energy γₐ of the adhesive film, which is obtained by Expression (1), is 30 to 70 mJ/m²
$${γ}_{a} = {γ}_{a}^{d} + {γ}_{a}^{p} \qquad Expression ( 1 )$$
in Expression (1),
γₐ^{d} and γₐ^{p} each represent a dispersion component and a polar component of the surface free energy of a surface of the adhesive film, which are derived based on Kaelbel-Uy theory.

17. A laminate comprising:
a carbon-containing support in which a carbon content in a depth region of 10 nm from a surface is 50% by mass or more, and
an adhesive film which is formed from the composition for forming an adhesive film according to claim 1 and is provided in contact with the carbon-containing support.

18. The laminate according to claim 17,
wherein a surface free energy γ_{ab} at an interface between the carbon-containing support and the adhesive film, which is obtained by Expression (2), is 5.0 mJ/m² or less,
$${γ}_{a b} = {( √ {γ}_{a}^{d} - √ {γ}_{b}^{d} )}^{2} + {( √ {γ}_{a}^{p} - √ {γ}_{b}^{p} )}^{2} \qquad Expression ( 2 )$$
in Expression (2),
γₐ^{d} and γₐ^{p} each represent a dispersion component and a polar component of a surface free energy of a surface of the adhesive film, which are derived based on Kaelbel-Uy theory, and
γ_{b}^{d} and γ_{b}^{p} each represent a dispersion component and a polar component of a surface free energy of a surface of the carbon-containing support, which are derived based on Kaelbel-Uy theory.

19. A method for manufacturing a laminate, comprising:
applying the composition for forming an adhesive film according to claim 1 onto a carbon-containing support in which a carbon content in a depth region of 10 nm from a surface is 50% by mass or more to form an adhesive film.

20. A pattern producing method comprising:
applying a composition for forming a pattern onto the adhesive film obtained by the method for manufacturing a laminate according to claim 19;
curing the composition for forming a pattern in a state of being in contact with a mold; and
peeling off the mold from the composition for forming a pattern.

21. A method for manufacturing a semiconductor element, comprising:
using the pattern obtained by the pattern producing method according to claim 20 to manufacture a semiconductor element.
